(19) United States
(12) Patent Application Publication
(10) Pub. No.: US 2024/0199883 A1
(43) Pub. Date: Jun. 20, 2024

(54) CORE-SHELL DYE, NEAR-INFRARED ABSORBING COMPOSITION INCLUDING THE SAME, AND NEAR-INFRARED ABSORBING FILM

(71) Applicant: SAMSUNG SDI CO., LTD., Yongin-si, Gyeonggi-do (KR)

(72) Inventors: Euisoo JEONG, Suwon-si, Gyeonggi-do (KR); Insub SHIN, Suwon-si, Gyeonggi-do (KR); Gyuseok HAN, Suwon-si, Gyeonggi-do (KR); Chaehyuk KO, Suwon-si, Gyeonggi-do (KR); Baek Soung PARK, Suwon-si, Gyeonggi-do (KR)

(21) Appl. No.: 18/281,826

(22) PCT Filed: Aug. 19, 2022
(86) PCT No.: PCT/KR2022/012437

§ 371 Date: Sep. 13, 2023

(30) Foreign Application Priority Data
Feb. 24, 2022 (KR) 10-2022-0024687

(51) Int. Cl. C09B 57/00; C09B 67/02; C09B 67/08; G03F 7/00; G03F 7/004

(52) U.S. Cl. CPC C09B 57/007; C09B 67/0004; C09B 67/0097; G03F 7/0007; G03F 7/004

(57) ABSTRACT

This disclosure relates to a core-shell dye, a near-infrared absorbing resin composition including the same, and a near-infrared absorbing film. Specifically, an embodiment provides a core-shell dye consisting of a core represented by Chemical Formula 1; and a shell surrounding the core and represented by Chemical Formula 2:

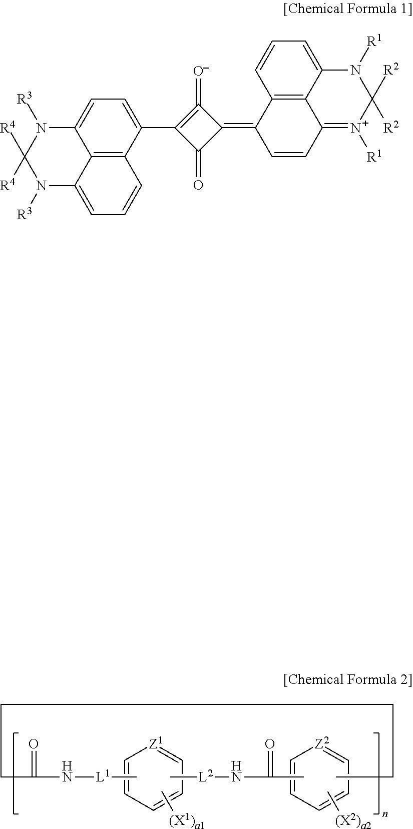

(In Chemical Formulas 1 and 2, each substituent is as defined in the specification.)

### TECHNICAL FIELD

This disclosure relates to a core-shell dye, a near-infrared absorbing resin composition including the same, and a near-infrared absorbing film.

### BACKGROUND ART

An image sensor is a semiconductor that converts photons into electrons and displays them on a display device or stores them in a storage device.

The image sensor is classified into a charge coupled device (CCD) image sensor and a complementary metal-oxide semiconductor (CMOS) image sensor according to a manufacturing process and an application method.

in addition, the CMOS image sensor includes a color filter including filter segments of additive and mixed primary colors of red, green, and blue. On the other hand, since a silicon-based photodiode (Si-Photodiode) of the CMOS image sensor has sensitivity in a near-infrared wavelength region (specifically, 750 nm to 1,000 nm), an optical filter including near-infrared absorbing film also needs to be provided therewith.

The near-infrared absorbing film serves to reduce or prevent optical distortion caused by light (e.g., near-infrared ray) other than a visible light region and in general, is formed by coating and drying a composition including a specific compound.

As for the compound for forming the near-infrared absorbing film, inorganic dyes are known. However, the inorganic dyes correspond to a material having near-infrared absorption intensity and thus should be used in an excessive amount to form the near-infrared absorbing film. In this way, the more the inorganic dyes are used, the higher viscosity the composition has, resulting in deteriorating processability and thickening the film.

Accordingly, the inorganic dyes as the compound for forming the near-infrared absorbing film are required to be replaced with organic dyes, but the organic dyes known to date have a problem of inferior durability (e.g., chemical resistance, light resistance, etc.) to the inorganic dyes, organic pigments, etc.

### DISCLOSURE

### Technical Problem

An embodiment provides a core-shell dye exhibiting high near-infrared absorption intensity and ensuring durability.

Another embodiment provides a near-infrared absorbing composition including the core-shell dye.

Another embodiment provides a near-infrared absorbing film manufactured using the near-infrared absorbing composition.

### Technical Solution

An embodiment provides a core-shell dye consisting of a core represented by Chemical Formula 1; and a shell surrounding the core and represented by Chemical Formula 2:

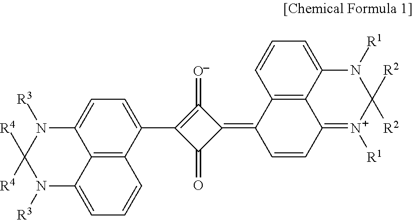

In Chemical Formula 1, R¹ is the same or different and is a substituted or unsubstituted C1 to C30 alkyl group, or a substituted or unsubstituted C6 to C30 aryl group; R² is the same or different and is a substituted or unsubstituted C1 to C30 alkyl group, a substituted or unsubstituted C6 to C30 aryl group, or a substituted or unsubstituted C1 to C30 arylalkyl group; or adjacent two R²s are linked to each other to form a substituted or unsubstituted C3 to C30 cycloalkyl ring; R³ is the same or different and is a substituted or unsubstituted C1 to C30 alkyl group, or a substituted or unsubstituted C6 to C30 aryl group, and R⁴ is the same or different and is a substituted or unsubstituted C1 to C30 alkyl group, a substituted or unsubstituted C6 to C30 aryl group, or a substituted or unsubstituted C1 to C30 arylalkyl group; or adjacent two R⁴ s are linked to each other to form a substituted or unsubstituted C3 to C30 cycloalkyl ring;

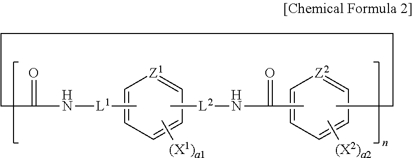

wherein, in Chemical Formula 2, L¹ and L² are each independently a substituted or unsubstituted C1 to C10 alkylene group; Z¹ and Z² are each independently *—CR—* or a nitrogen atom, wherein R is a hydrogen atom or a substituted or unsubstituted C1 to C10 alkyl group; X¹ and X² are each independently a halogen or a substituted or unsubstituted C1 to C10 alkyl group; a1 and a2 are independently an integer of 0 to 4; and n is an integer of 2 or more.

R¹ may be the same or different and may be a substituted or unsubstituted C1 to C10 alkyl group, or a substituted or unsubstituted C6 to C10 aryl group; and a substituent of R¹ may be at least one (meth)acrylate group, at least one *—O—* (epoxy) group, or a combination thereof.

R² may be the same or different and may be a substituted or unsubstituted C1 to C10 alkyl group or a substituted or unsubstituted C1 to C10 arylalkyl group; or adjacent two R² s may be linked to each other to form a C1 to C10 cycloalkyl ring that is substituted or unsubstituted with a C1 to C5 alkyl group; and a substituent of R² may be at least one C1 to C5 alkyl group.

R³ may be the same or different and may be a substituted or unsubstituted C1 to C10 alkyl group, or a substituted or unsubstituted C6 to C10 aryl group; and a substituent of R³ may be at least one (meth)acrylate group, at least one *—O—* (epoxy) group, or a combination thereof.

R⁴ may be the same or different and is a substituted or unsubstituted C1 to C10 alkyl group or a substituted or unsubstituted C1 to C10 arylalkyl group; or adjacent two R² s may be linked to each other to form a C1 to C10 cycloalkyl ring that is substituted or unsubstituted with a C1 to C5 alkyl group; and a substituent of R⁴ may be at least one C1 to C5 alkyl group.

The core represented by Chemical Formula 1 may have a symmetrical structure.

The core represented by Chemical Formula 1 may be represented by any one of Chemical Formulas 1-1 to 1-4:

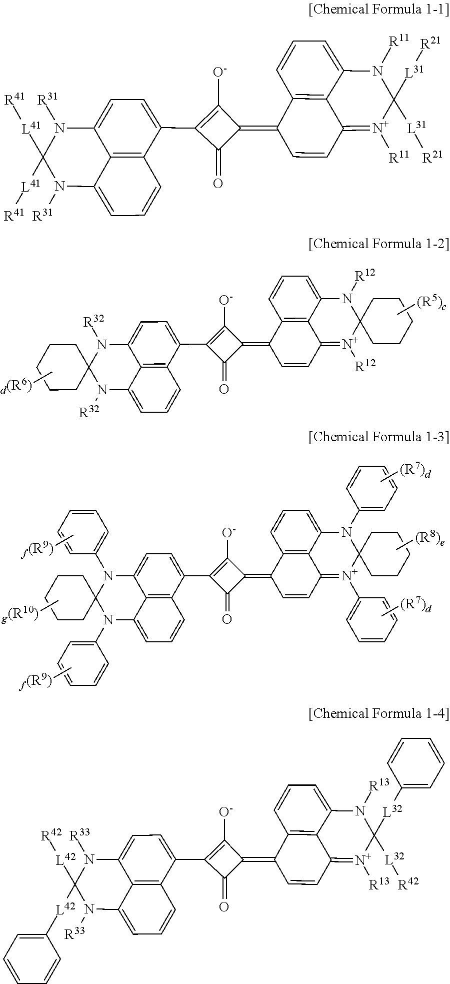

In Chemical Formulas 1-1 to 1-4, R¹¹, R¹², R¹³, R²¹, R³¹, R³², R³³, R⁴¹, and R⁴² may each independently be the same or different and may be a C1 to C10 alkyl group; L³¹, L³². L⁴¹, and L⁴² are independently the same or different and are a C1 to C10 alkylene group; R⁵, R⁶, R⁸, and R¹⁰ are independently the same or different and are a C1 to C10 alkyl group; R⁷ and R⁹ may each independently be the same or different and may be a (meth)acrylate group or a *—O—*(epoxy) group; and c, d, e, f, and g are each independently an integer of 0 to 5.

The core represented by Chemical Formula 1 may be represented by any one of the following groups:

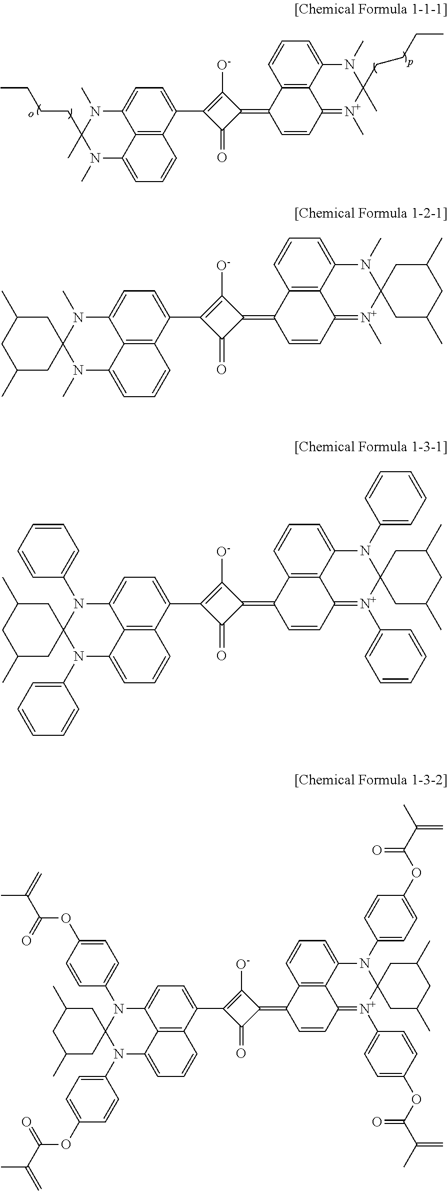

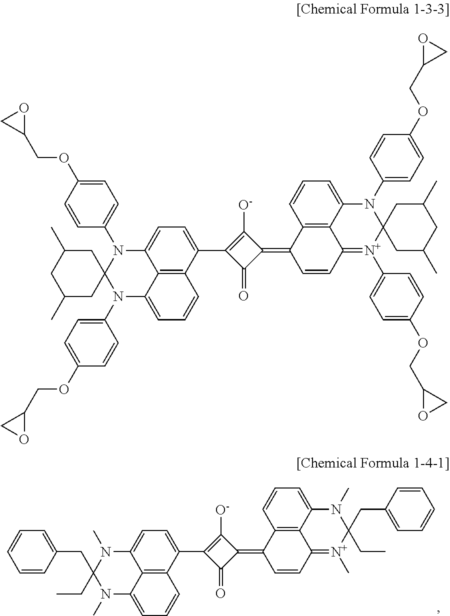

In Chemical Formula 1-1-1, o and p are each independently an integer of 0 to 5.

Any one of Z¹ and Z² may be *—CH—* or a nitrogen atom, and the other may be *—CH—*.

X¹ and X² may each independently represent a halogen group, and a1+a2 may be an integer of 1 to 8.

L¹ and L² may each independently be a C1 to C10 alkylene group.

The n may be 2.

The shell may be represented by any one of Chemical Formulas 2-1 to 2-4:

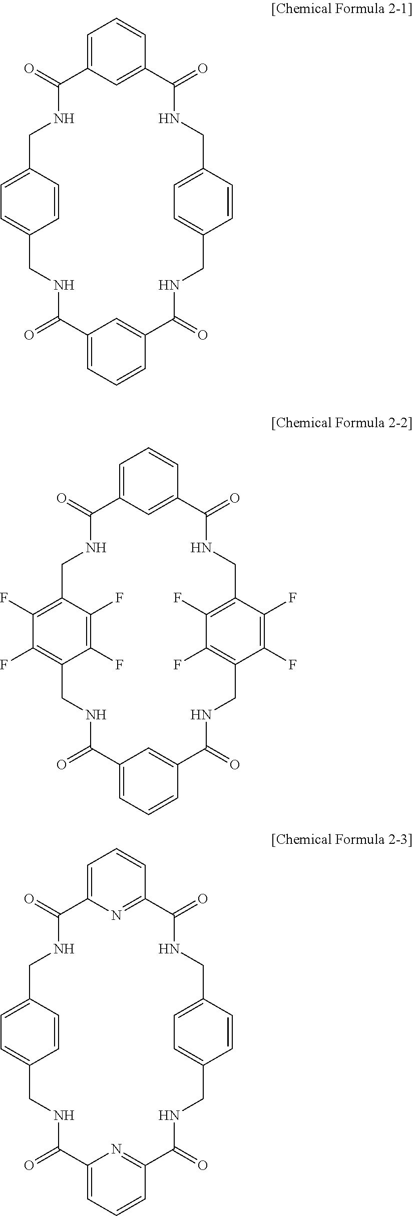 [SMILES: O=C1NCc2ccc(cc2)CNC(=O)c2cccc(c2)C(=O)NCc2ccc(cc2)CNC(=O)c2cccc1c2 ; O=C1NCc2c(F)c(F)c(c(F)c2F)CNC(=O)c2cccc(c2)C(=O)NCc2c(F)c(F)c(c(F)c2F)CNC(=O)c2cccc1c2 ; O=C1NCc2ccc(cc2)CNC(=O)c2cccc(n2)C(=O)NCc2ccc(cc2)CNC(=O)c2cccc1n2]

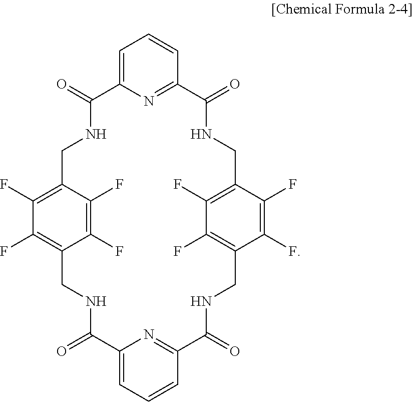 [SMILES: O=C1NCc2c(F)c(F)c(c(F)c2F)CNC(=O)c2cccc(n2)C(=O)NCc2c(F)c(F)c(c(F)c2F)CNC(=O)c2cccc1n2]

The core-shell dye may include the core and the shell in a mole ratio of 1:1.

The core-shell dye may be represented by any one selected from the following group:

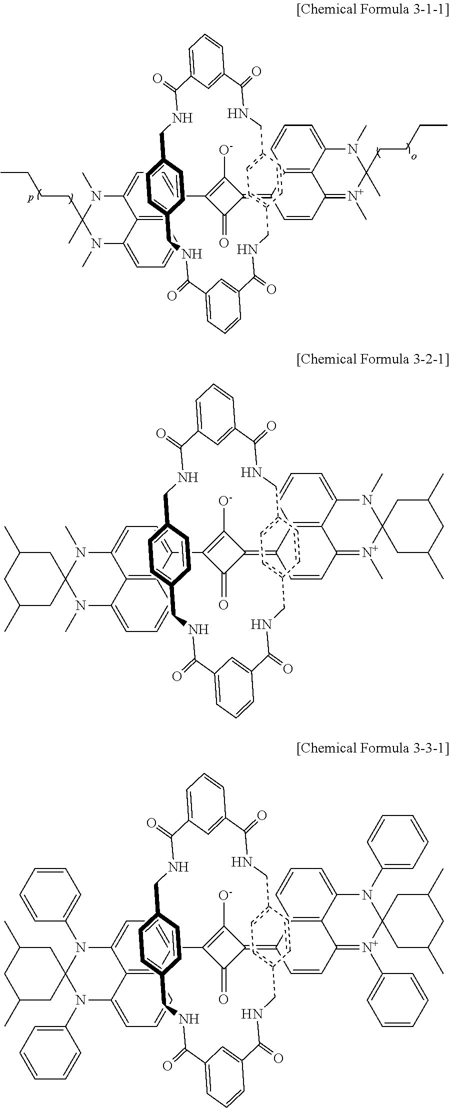

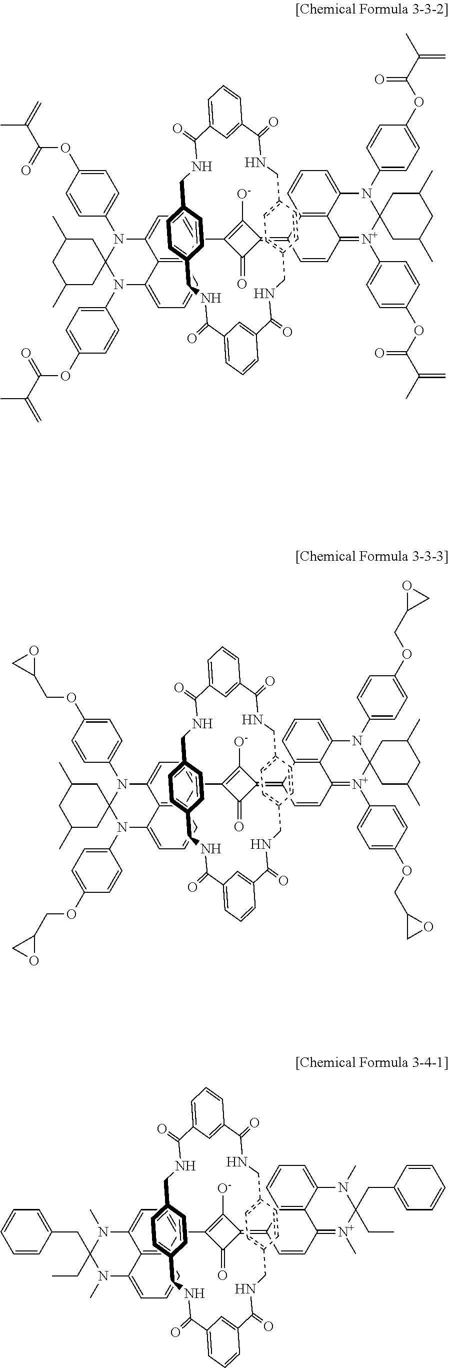

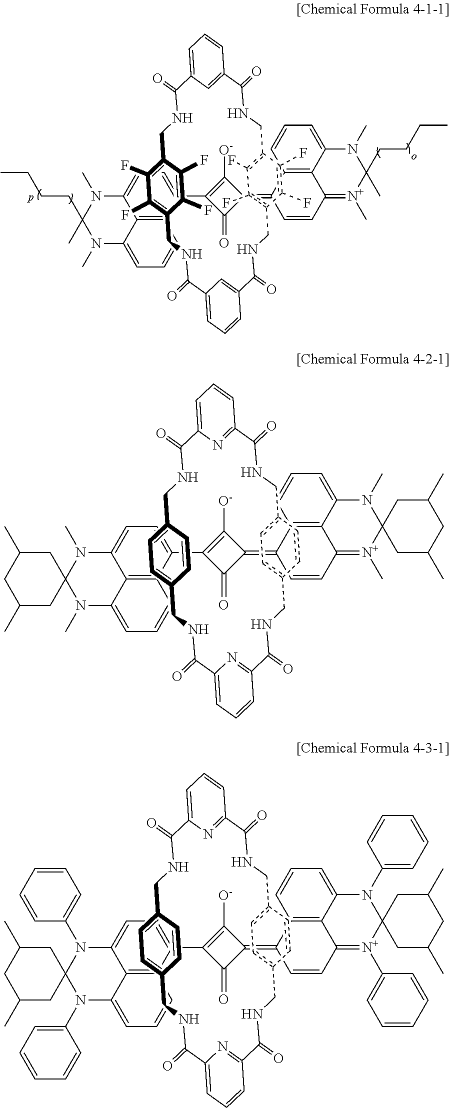

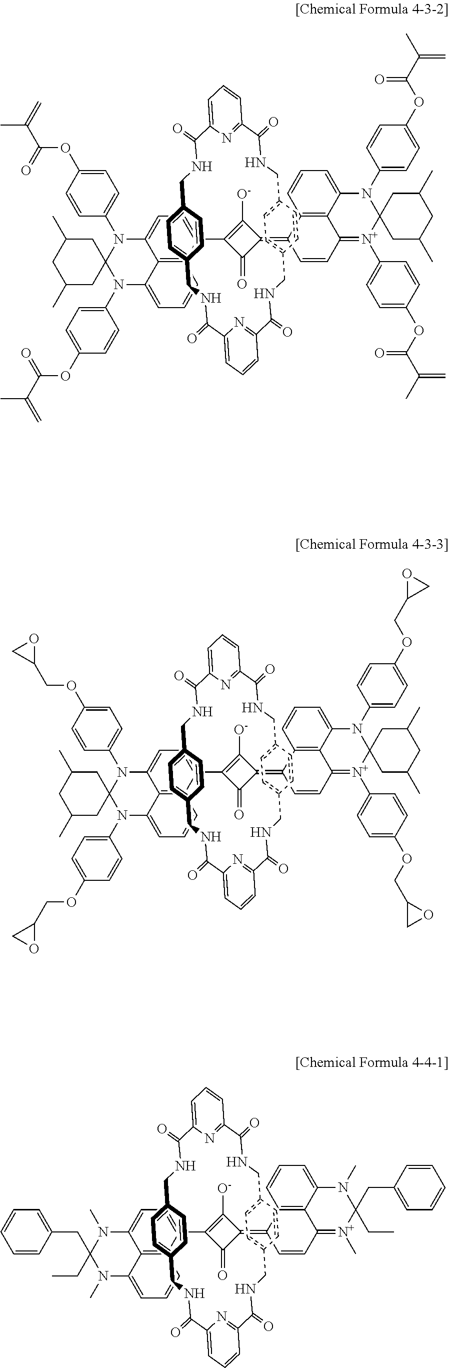

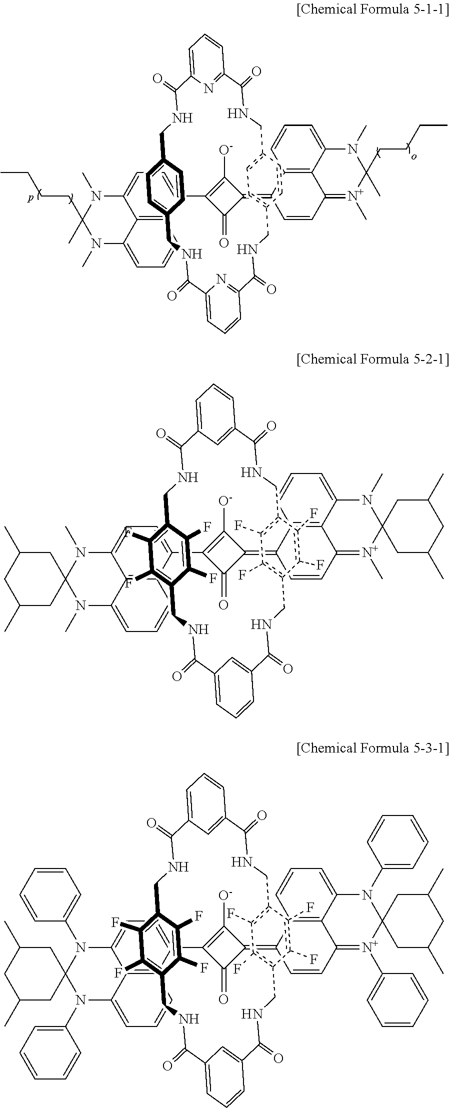

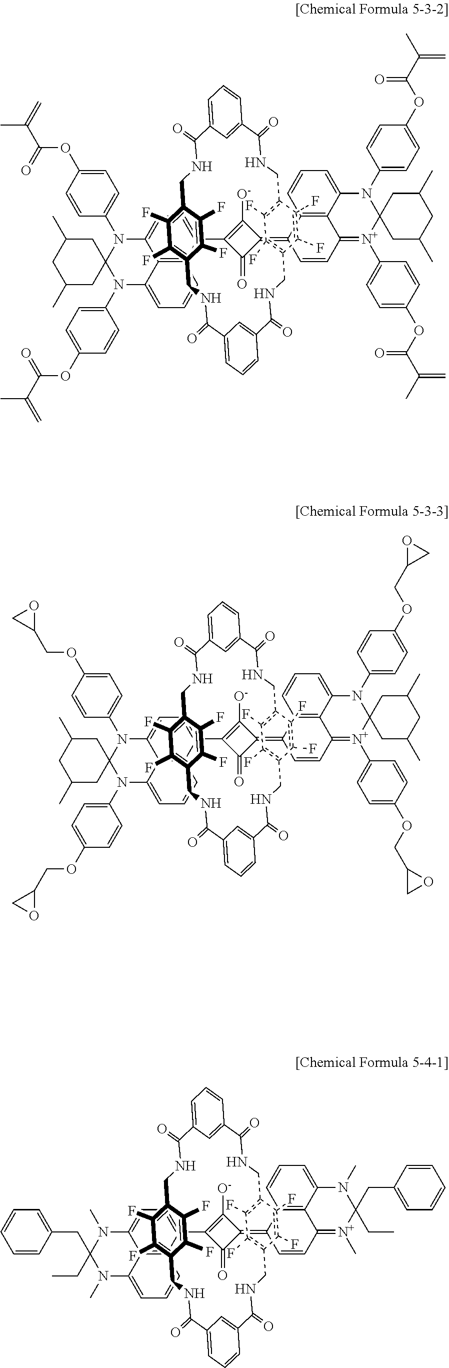

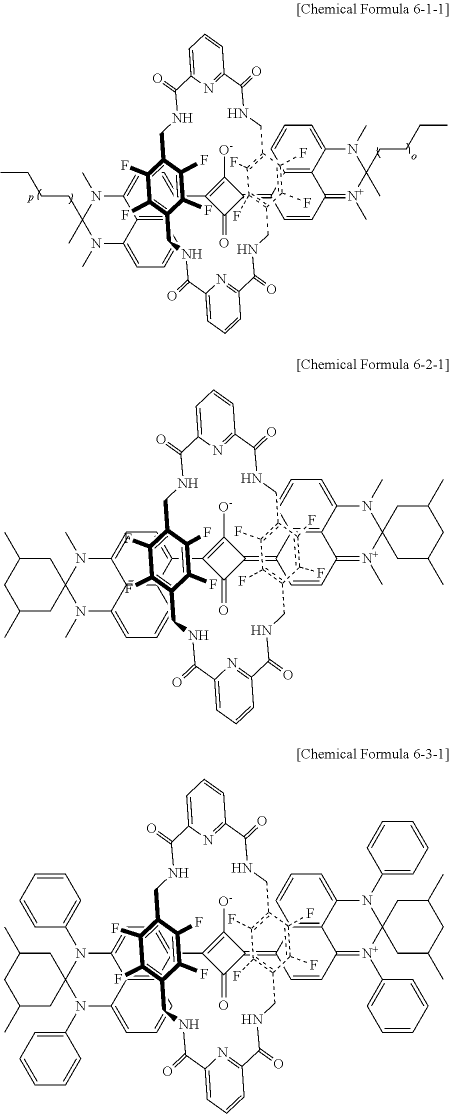

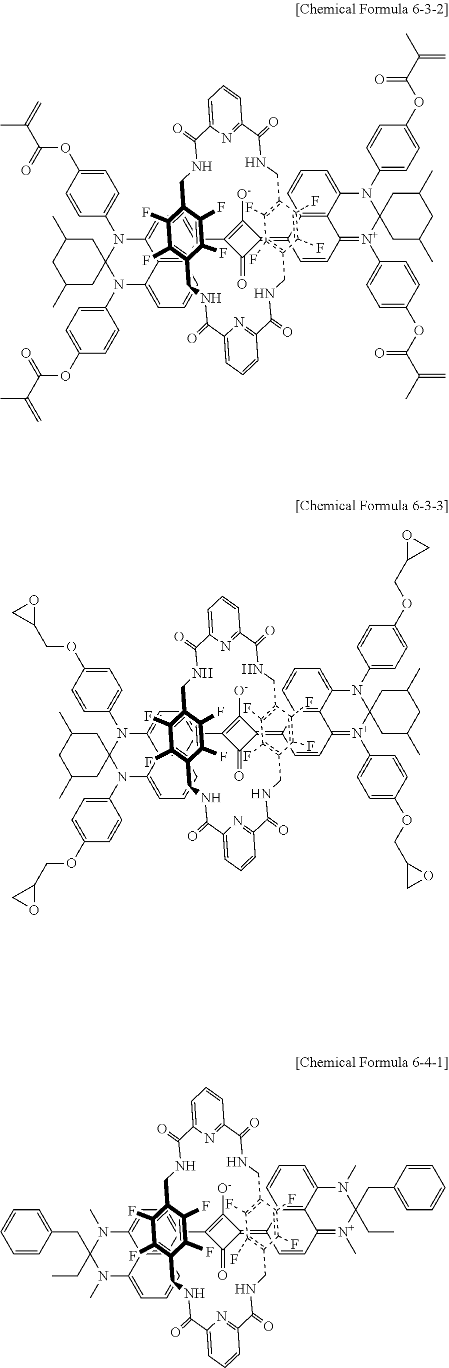

In Chemical Formula 3-1-1, Chemical Formula 4-1-1, Chemical Formula 5-1-1, and Chemical Formula 6-1-1, o and p may each independently be an integer of 0 to 5.

The core may have a maximum absorption peak at a wavelength of 700 nm to 850 nm.

The core-shell dye may have a maximum absorption peak at a wavelength of 700 nm to 1,000 nm.

The core-shell dye may be a near-infrared absorbing dye.

Another embodiment provides a near-infrared absorbing resin composition including the core-shell dye.

The near-infrared absorbing resin composition may further include a binder resin and a solvent.

The near-infrared absorbing resin composition may be used for a CMOS image sensor.

Another embodiment provides a near-infrared absorbing film manufactured using a near-infrared absorbing resin composition.

Another embodiment provides an optical filter including the near-infrared absorbing film.

Another embodiment provides a CMOS image sensor including the optical filter.

Other embodiments of the present invention are included in the following detailed description.

### Advantageous Effects

The core-shell dye according to an embodiment may simultaneously secure light resistance, chemical resistance, heat resistance, and the like while exhibiting excellent matching properties with a near-infrared absorption wavelength band.

Accordingly, the near-infrared absorbing resin composition including the core-shell dye can form a fine pattern while reducing the dye content, contributing to economically providing a near-infrared absorbing film for a CMOS image sensor.

### DESCRIPTION OF THE DRAWINGS

FIG. 1 is a view showing the cage width of the shell represented by Chemical Formula 2.

### MODE FOR INVENTION

Hereinafter, embodiments of the present invention are described in detail. However, these embodiments are exemplary, the present invention is not limited thereto and the present invention is defined by the scope of claims.

In the present specification, when specific definition is not otherwise provided, “substituted” refers to replacement of at least one hydrogen of a compound by a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

In the present specification, when specific definition is not otherwise provided, “heterocycloalkyl group”, “heterocycloalkenyl group”, “heterocycloalkynyl group,” and “heterocycloalkylene group” refer to presence of at least one N, O, S, or P in a cyclic compound of cycloalkyl, cycloalkenyl, cycloalkynyl, and cycloalkylene.

In the present specification, when specific definition is not otherwise provided, “(meth)acrylate” refers to both “acrylate” and “methacrylate”.

In the present specification, when specific definition is not otherwise provided, “combination” refers to mixing or copolymerization.

In the chemical formula of the present specification, unless a specific definition is otherwise provided, hydrogen is boned at the position when a chemical bond is not drawn where supposed to be given.

In the present specification, when specific definition is not otherwise provided, when a plurality of substituents having the same number exist, these substituents are the same or different. For example, when there are four “X₁”s in Chemical Formula 2 to be described later, all four “X₁”s may be the same as “F”; one “X₁” may be “F”, two “X₁”s may be “C1”, and one “X₁” may be “Br”. However, these are examples.

In addition, as used herein, when specific definition is not otherwise provided, a dotted line “ [symbol] ” or “*” means a portion linked to the same or different atoms or chemical formulas.

### (Core-Shell Dye)

The present invention relates to a compound for producing a near-infrared absorbing film, and an object thereof is an organic compound-based colorant that exhibits high near-infrared absorption intensity and simultaneously secures light resistance, chemical resistance, heat resistance, and the like.

Specifically, an embodiment provides a core-shell dye consisting of a core represented by Chemical Formula 1; and a shell surrounding the core and represented by Chemical Formula 2:

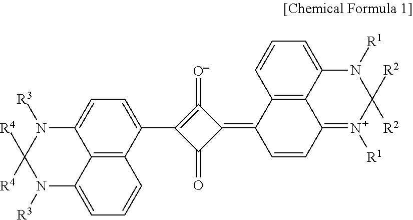

In Chemical Formula 1, R¹ is the same or different and is a substituted or unsubstituted C1 to C30 alkyl group, or a substituted or unsubstituted C6 to C30 aryl group; R² is the same or different and is a substituted or unsubstituted C1 to C30 alkyl group, a substituted or unsubstituted C6 to C30 aryl group, or a substituted or unsubstituted C1 to C30 arylalkyl group; or adjacent two R e s are linked to each other to form a substituted or unsubstituted C3 to C30 cycloalkyl ring; R³ is the same or different and is a substituted or unsubstituted C1 to C30 alkyl group, or a substituted or unsubstituted C6 to C30 aryl group, and R⁴ is the same or different and is a substituted or unsubstituted C1 to C30 alkyl group, a substituted or unsubstituted C6 to C30 aryl group, or a substituted or unsubstituted C1 to C30 arylalkyl group; or adjacent two R⁴ s are linked to each other to form a substituted or unsubstituted C3 to C30 cycloalkyl ring;

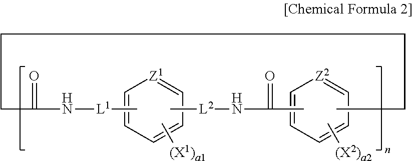

wherein, in Chemical Formula 2, L¹ and L² are each independently a substituted or unsubstituted C1 to C10 alkylene group; Z¹ and Z² are each independently *—CR—* or a nitrogen atom, wherein R is a hydrogen atom or a substituted or unsubstituted C1 to C10 alkyl group; X¹ and X² are each independently a halogen or a substituted or unsubstituted C1 to C10 alkyl group; a1 and a2 are independently an integer of 0 to 4; and n is an integer of 2 or more.

The core represented by Chemical Formula 1 is a compound having a structure in which an aniline moiety in a squarine (SQ)-based compound is replaced with a diamine naphthalene moiety, and the maximum absorption peak may shift to the long wavelength region compared to a squarine-based compound. In this way, the shift of the maximum absorption peak toward the long wavelength region means further improvement of matching properties with the near-infrared absorption wavelength band.

Specifically, the core represented by Chemical Formula 1 has a maximum absorption peak at a wavelength of 700 nm to 850 nm, wherein the maximum absorption peak has higher intensity than that of an inorganic dye. In addition, the core represented by Chemical Formula 1 is an organic dye forming no particles, which is advantageous over an organic pigment.

Accordingly, the core-shell dye including the core represented by Chemical Formula 1, compared to the inorganic dye, the organic pigment, etc., is advantageous in reducing an amount used for forming the near-infrared absorbing film, increasing processability, thinning the film, and the like as well as exhibits excellent wavelength matching properties.

On the other hand, the core represented by Chemical Formula 1 has inferior durability to that of the inorganic dye, the organic pigment, etc. The shell represented by Chemical Formula 2 is a type of macrocyclic compound having so sufficient a size as to surround the core represented by Chemical Formula 1 and thus may compensate for lack of durability of the core represented by Chemical Formula 1.

Furthermore, a core-shell dye of which a halogen group is not introduced into the shell represented by Chemical Formula 2 may exhibit a maximum absorption peak at 700 nm to 850 nm, but when the halogen group is introduced into the shell represented by Chemical Formula 2, the core-shell dye may exhibit a maximum absorption peak at 850 nm to 1,000 nm. As the halogen group is introduced into the shell represented by Chemical Formula 2, a shift of the maximum absorption peak of the core-shell dye toward the long wavelength region means further improvement of matching properties with the near-infrared absorption wavelength band.

Comprehensively, the core-shell dye according to an embodiment exhibits excellent matching properties with the near-infrared absorption wavelength band as a single effect of the core represented by Chemical Formula 1; or as a synergic effect of the core represented by Chemical Formula 1 and the shell represented by Chemical Formula 2. In addition, the core-shell dye according to an embodiment has excellent durability due to the shell represented by Chemical Formula 2 surrounding the core represented by Chemical Formula 1.

Hereinafter, a core-shell dye of one embodiment will be described in more detail.

### Core Represented by Chemical Formula 1

In the core represented by Chemical Formula 1, 10 may be the same or different and may be a substituted or unsubstituted C1 to C10 alkyl group, or a substituted or unsubstituted C6 to C10 aryl group; and when R¹ is substituted, the substituent may be at least one (meth)acrylate group, at least one *—O—* (epoxy) group, or a combination thereof.

Specifically, R¹ may be a methyl group or a phenyl group; R¹ may be unsubstituted or substituted; and when R¹ is substituted, the substituent may be a (meth)acrylate group or a *—O—* (epoxy) group.

The (meth)acrylate group is a functional group contributing to improvement in heat resistance, and the *—O—* (epoxy) group is a functional group contributing to improvement in chemical resistance. Therefore, in preparation for the case where R¹ is unsubstituted, when it is substituted with at least one (meth)acrylate group, at least one *—O—* (epoxy) group, or a combination thereof, chemical resistance, heat resistance, etc. of the core may be improved appropriately.

R² may be the same or different and may be a substituted or unsubstituted C1 to C10 alkyl group or a substituted or unsubstituted C1 to C10 arylalkyl group; or adjacent two R² s may be linked to each other to form a C1 to C10 cycloalkyl ring that is substituted or unsubstituted with a C1 to C5 alkyl group; and a substituent of R² may be at least one C1 to C5 alkyl group.

Specifically, R² may be a C1 to C10 alkyl group or a benzyl group (*—CH₂—C₆H₅); and R² may be unsubstituted.

Alternatively, two adjacent R² s may be linked to each other to form a C6 cycloalkyl ring; in this case, the C6 cycloalkyl ring may be unsubstituted or substituted; and when the C6 cycloalkyl ring is substituted, substituents thereof may be two methyl groups.

R³ may be the same or different and may be a substituted or unsubstituted C1 to C10 alkyl group or a substituted or unsubstituted C6 to C10 aryl group; when R³ is substituted, a substituent thereof may be at least one (meth)acrylate group, at least one *—O—* (epoxy) group, or a combination thereof.

Specifically, R³ may be a methyl group or a phenyl group; le may be unsubstituted or substituted; when the R³ is substituted, a substituent thereof may be a (meth)acrylate group or a *—O—* (epoxy) group.

The (meth)acrylate group is a functional group contributing to improvement in heat resistance, and the *—O-(epoxy) group is a functional group contributing to improvement in chemical resistance. Therefore, in preparation for the case where R³ is unsubstituted, when it is substituted with at least one (meth)acrylate group, at least one *—O—* (epoxy) group, or a combination thereof, chemical resistance, heat resistance, etc. of the core may be improved appropriately.

wherein R⁴ is, identically or differently, a substituted or unsubstituted C1 to C10 alkyl group or a substituted or unsubstituted C1 to C10 arylalkyl group; adjacent two R e s may be linked to each other to form a C1 to C10 cycloalkyl ring unsubstituted or substituted with a C1 to C5 alkyl group; and a substituent of R² may be at least one C1 to C5 alkyl group.

Specifically, R⁴ may be a C1 to C10 alkyl group or a benzyl group (*—CH₂—C₆H₅); and R⁴ may be unsubstituted.

Alternatively, two adjacent R⁴ s may be linked to each other to form a C6 cycloalkyl ring; in this case, the C6 cycloalkyl ring may be unsubstituted or substituted; and when the C6 cycloalkyl ring is substituted, a substituent thereof may be two methyl groups.

The core represented by Chemical Formula 1 may have a symmetrical structure.

Specifically, le may be the same as R³, and R² may be the same as R⁴. In this case, the synthesis mechanism is easy in preparation for the case where the core represented by Chemical Formula 1 has an asymmetric structure, and accordingly, there are advantages such as yield increase, synthesis difficulty decrease, and cost reduction.

The core represented by Chemical Formula 1 may be represented by any one of Chemical Formulas 1-1 to 1-4:

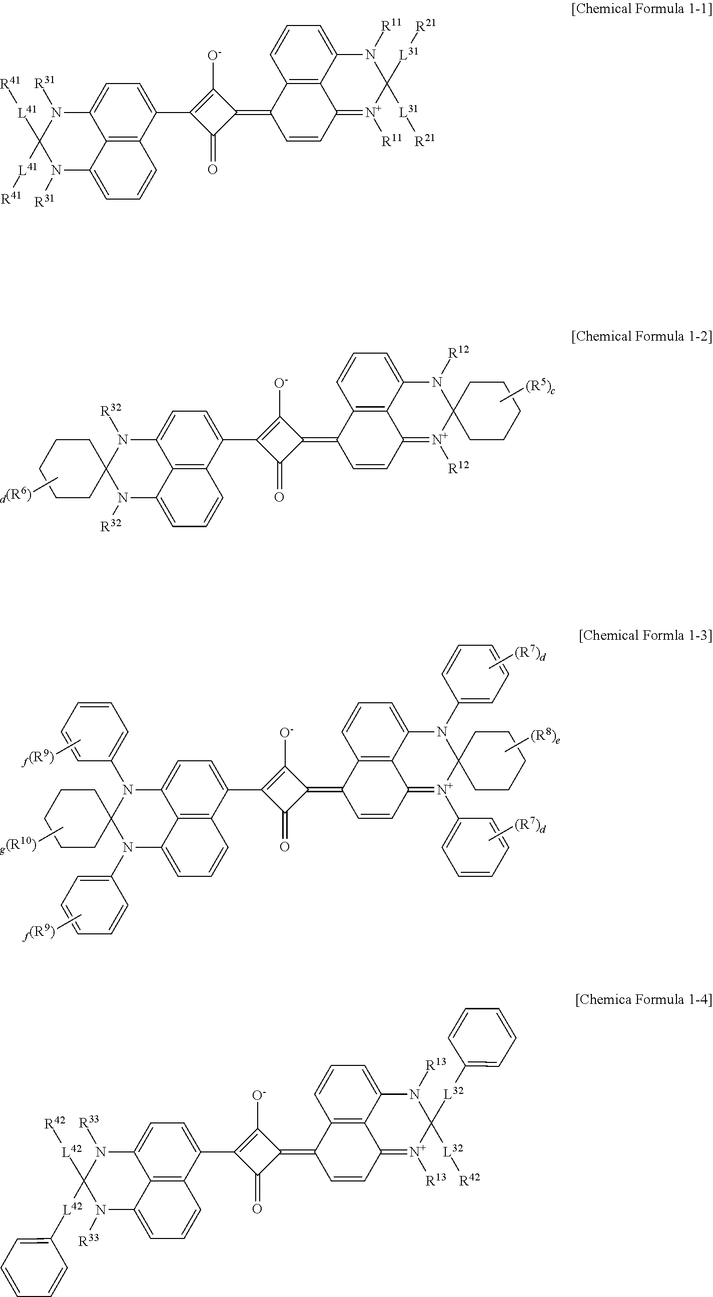

In Chemical Formulas 1-1 to 1-4, R¹¹, R¹², R¹³, R²¹, R³¹, R³², R³³, R⁴¹ and R⁴² may each independently be the same or different and may be a C1 to C10 alkyl group; L³¹, L³². L⁴¹ and L⁴² are independently the same or different and are a C1 to C10 alkylene group; R⁵, R⁶, R⁸ and R¹⁰ are independently the same or different and are a C1 to C10 alkyl group; R⁷ and R⁹ may each independently be the same or different and may be a (meth)acrylate group or a *—O—*(epoxy) group; and c, d, e, f, and g are each independently an integer of 0 to 5.

In particular, the core represented by Chemical Formula 1 may be represented by any one of the following groups:

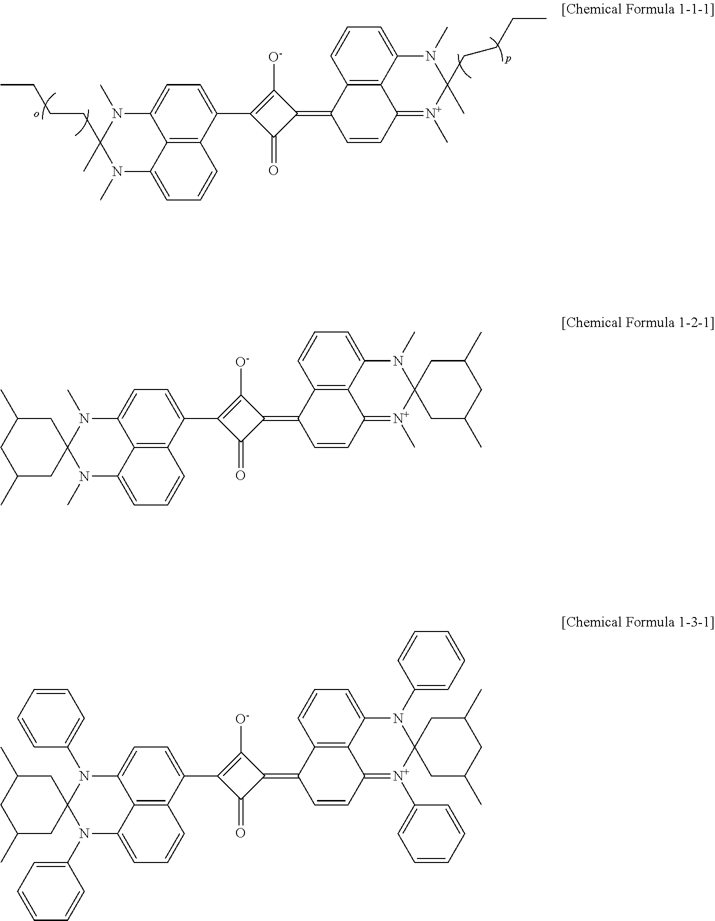

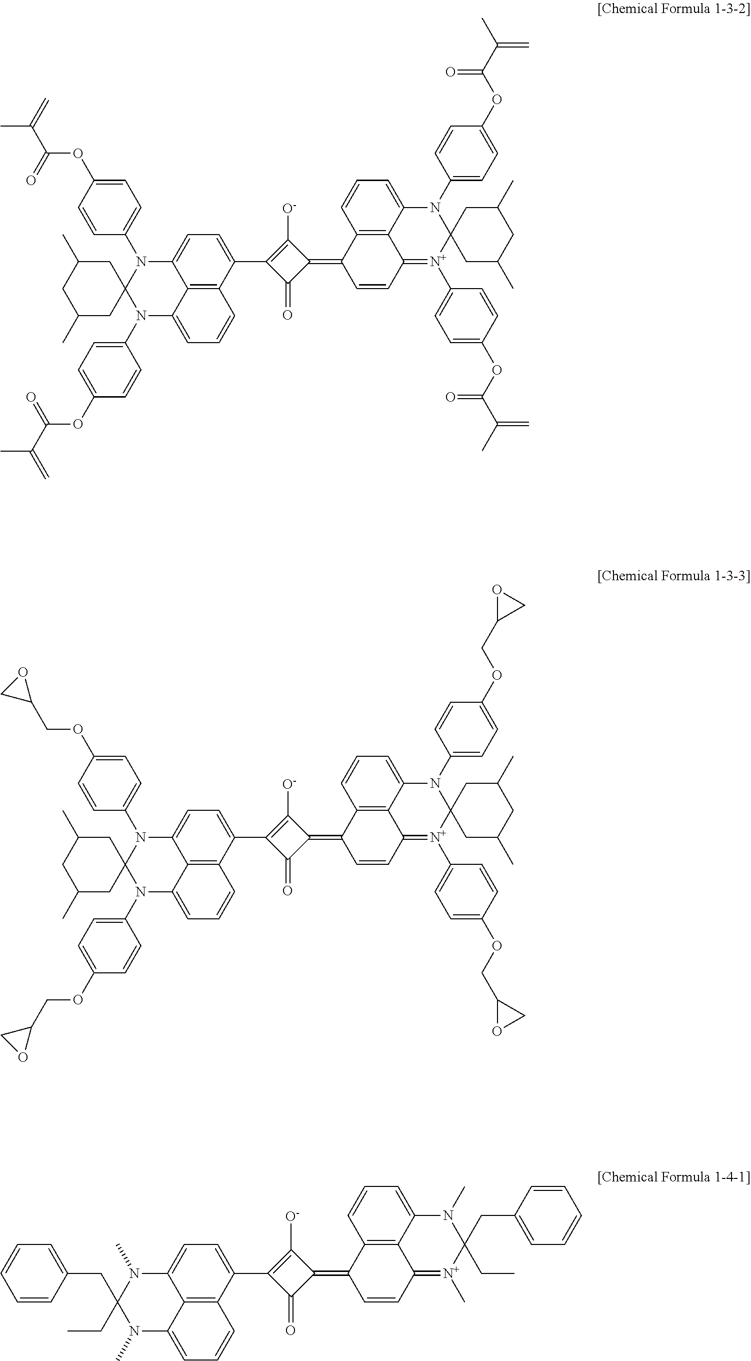

In Chemical Formula 1-1-1, o and p are each independently an integer of 0 to 5.

A length of the core represented by Chemical Formula 1 may be 1 nm to 3 nm, or for example 1.5 nm to 2 nm. When the core represented by Chemical Formula 1 has a length within the above range, a core-shell dye can be easily formed.

In other words, when the core represented by Chemical Formula 1 has a length within the range, a structure that a shell of the macrocyclic compound surrounds a compound represented by Chemical Formula 1 may be obtained. When other compounds having a length out of the range are used, since it is difficult to form the structure that the shell surrounds the core, durability may hardly be improved.

The core represented by Chemical Formula 1 itself may have a maximum absorption peak at a wavelength of 700 nm to 850 nm. The core-shell dye including the core having the above spectral characteristics may be applied to a composition for a near-infrared absorbing film of a CMOS image sensor. An optical filter including the near-infrared absorbing film may effectively transmit a wavelength of 350 nm to 650 nm while effectively implementing a near-infrared absorbing function.

However, the core-shell dye may have a different maximum absorption peak depending on whether a halogen group is introduced into the shell represented by Chemical Formula 2.

For reference, the core represented by Chemical Formula 1 includes three resonance structures, as shown in the following scheme, but in the present specification, only one structure is shown for the compound represented by Chemical Formula 1 for convenience:

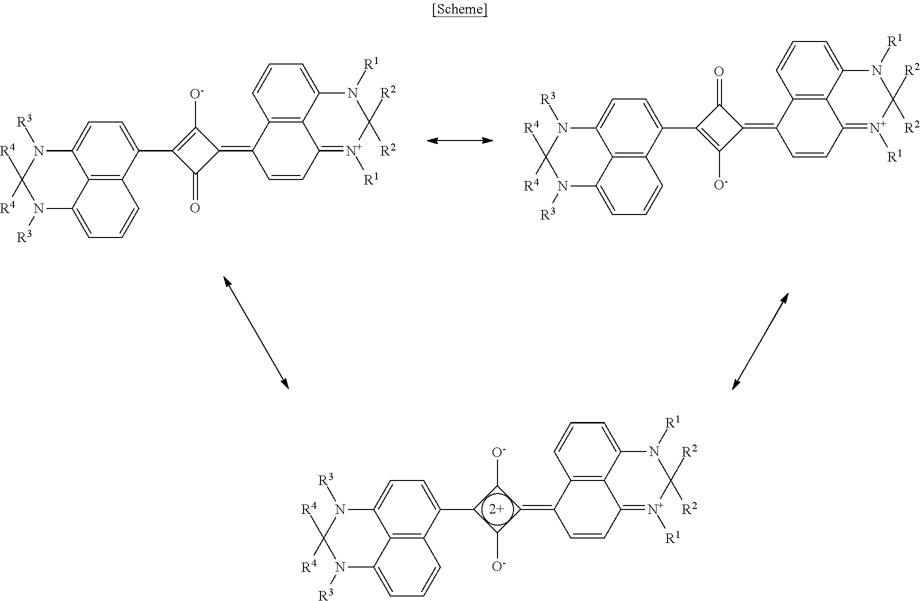

That is, the core represented by Chemical Formula 1 may be represented by any one of the three resonance structures.

### Shell Represented by Chemical Formula 2

The shell represented by Chemical Formula 2 is a Rotaxane-based macrocyclic compound, and includes an amide bond (—CONH—). Accordingly, a hydrogen atom included in the amide bond of the shell represented by Chemical Formula 2 may form a non-covalent bond with an oxygen atom of the compound represented by Chemical Formula 1. Specifically, these two atoms form a hydrogen bond and thus enhance the durability of the core-shell dye.

Specifically, any one of Z¹ and Z² may be *—CH—* or a nitrogen atom, and the other may be *—CH—*. Particularly, when a nitrogen atom is introduced into either one of Z¹ and Z², compared to when not introduced, non-covalent bonds of the shell and the core or inside the shell increase, thereby further enhancing the durability of the core-shell dye.

X¹ and X² may each independently be a halogen group, and d1+d2 may be an integer of 1 to 8. When a fluorine atom is introduced as at least one of X¹ and X², the maximum absorption peak of the core-shell dye shifts to the long wavelength region, and matching properties with the near infrared absorption wavelength band is improved, in contrast to the case where it is not introduced at all. For example, X¹ and X² may both be fluorine atoms (i.e., F), and a1+a2 may be 8.

L¹ and L² may each independently be a C1 to C10 alkylene group. In this case, the solubility is improved and a structure in which the shell surrounds the core may be easily formed. For example, both L¹ and L¹ may be methylene groups (i.e., *—CH₂—*).

The n may be 2.

The shell may be represented by any one of Chemical Formulas 2-1 to 2-4:

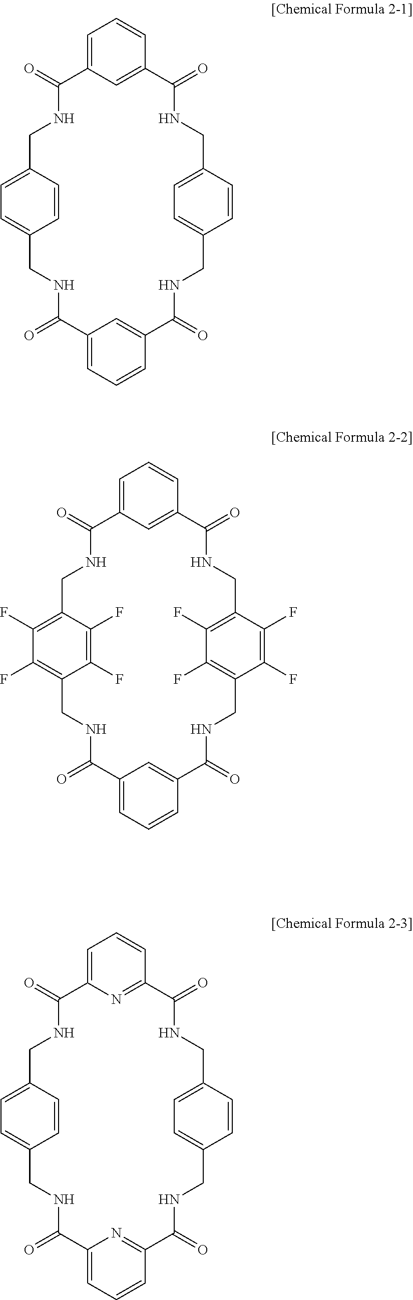 [SMILES: O=C1NCc2ccc(cc2)CNC(=O)c2cccc(c2)C(=O)NCc2ccc(cc2)CNC(=O)c2cccc1c2 ; O=C1NCc2c(F)c(F)c(c(F)c2F)CNC(=O)c2cccc(c2)C(=O)NCc2c(F)c(F)c(c(F)c2F)CNC(=O)c2cccc1c2 ; O=C1NCc2ccc(cc2)CNC(=O)c2cccc(n2)C(=O)NCc2ccc(cc2)CNC(=O)c2cccc1n2]

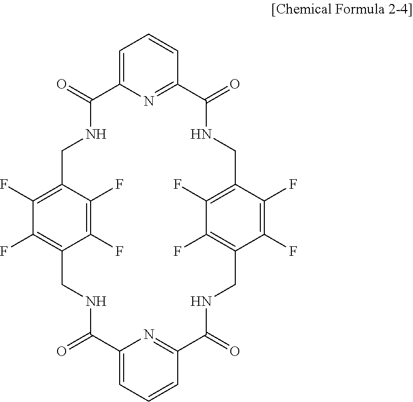 [SMILES: O=C1NCc2c(F)c(F)c(c(F)c2F)CNC(=O)c2cccc(n2)C(=O)NCc2c(F)c(F)c(c(F)c2F)CNC(=O)c2cccc1n2]

Among the above 2-1 to 2-4, when the structure of the mother nucleus is the same, there is an effect of shifting the maximum absorption peak of the core-shell dye using a shell substituted with a fluorine atom to a longer wavelength region.

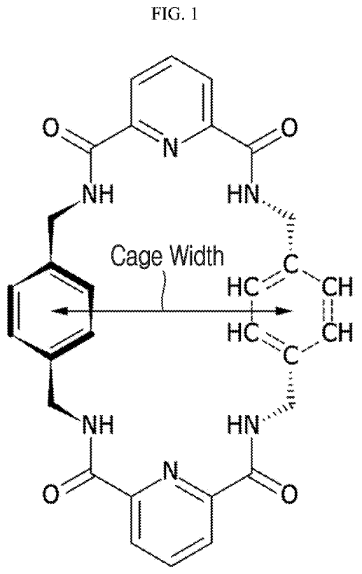

A cage width of the shell may range from 6.5 Å to 7.5 Å and a volume of the shell may range from 10 Å to 16 Å. The cage width in this disclosure refers to an internal distance of the shell, for example in a shell represented by Chemical Formula 2, a distance between two different phenylene groups in which both methylene groups are linked (See FIG. 1). When the shell has a cage width within the range, a core-shell dye having a structure surrounding the core represented by Chemical Formula 1 may be obtained, and thus a near-infrared absorbing film having improved durability and high luminance may be realized when the core-shell dye is added to a near-infrared absorbing resin composition.

### Core-Shell Dye

On the other hand, the core-shell dye may include a core including the compound represented by Chemical Formula 1 and the shell in a mole ratio of 1:1. When the core and the shell are present in the mole ratio, a coating layer (shell) surrounding the core including the compound represented by Chemical Formula 1 may be well formed.

Representative examples of the core-shell dye are as follows:

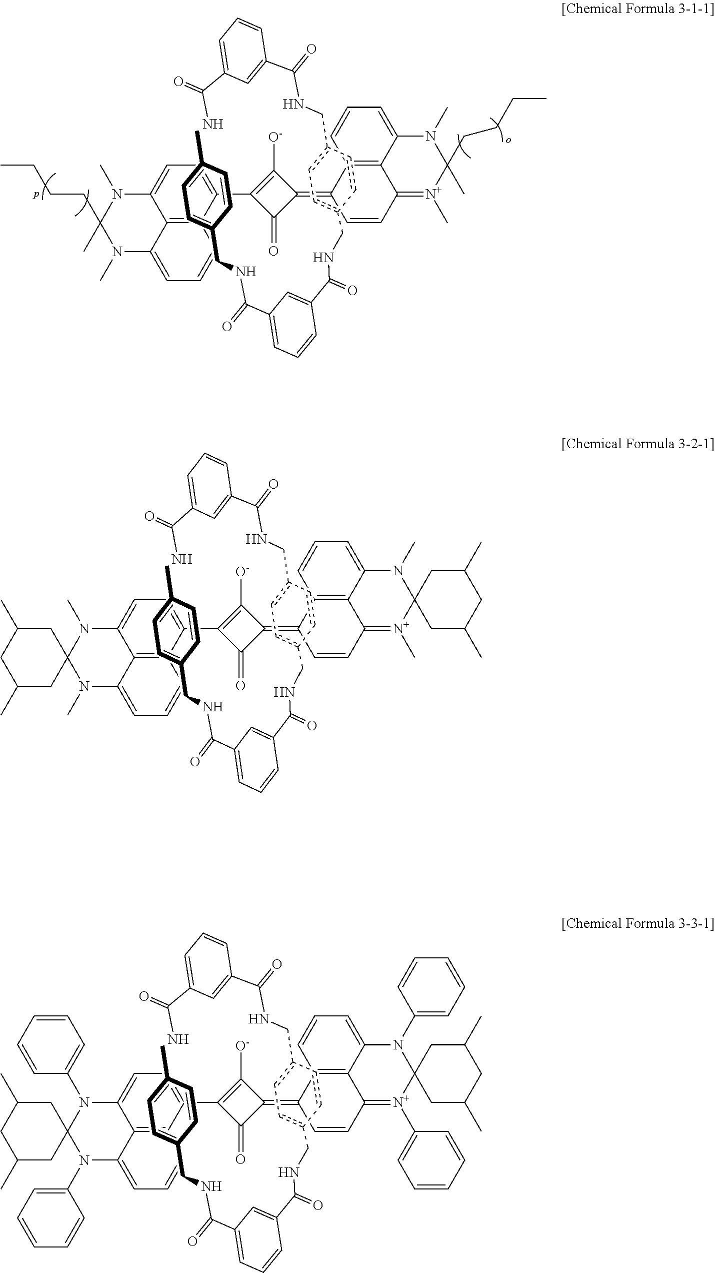

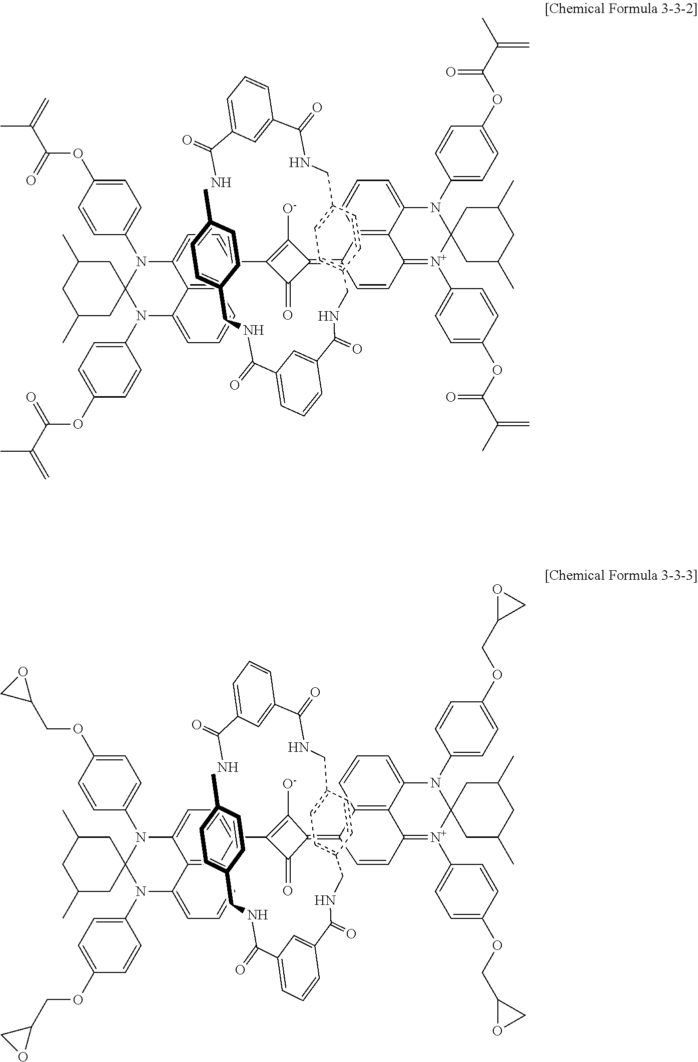

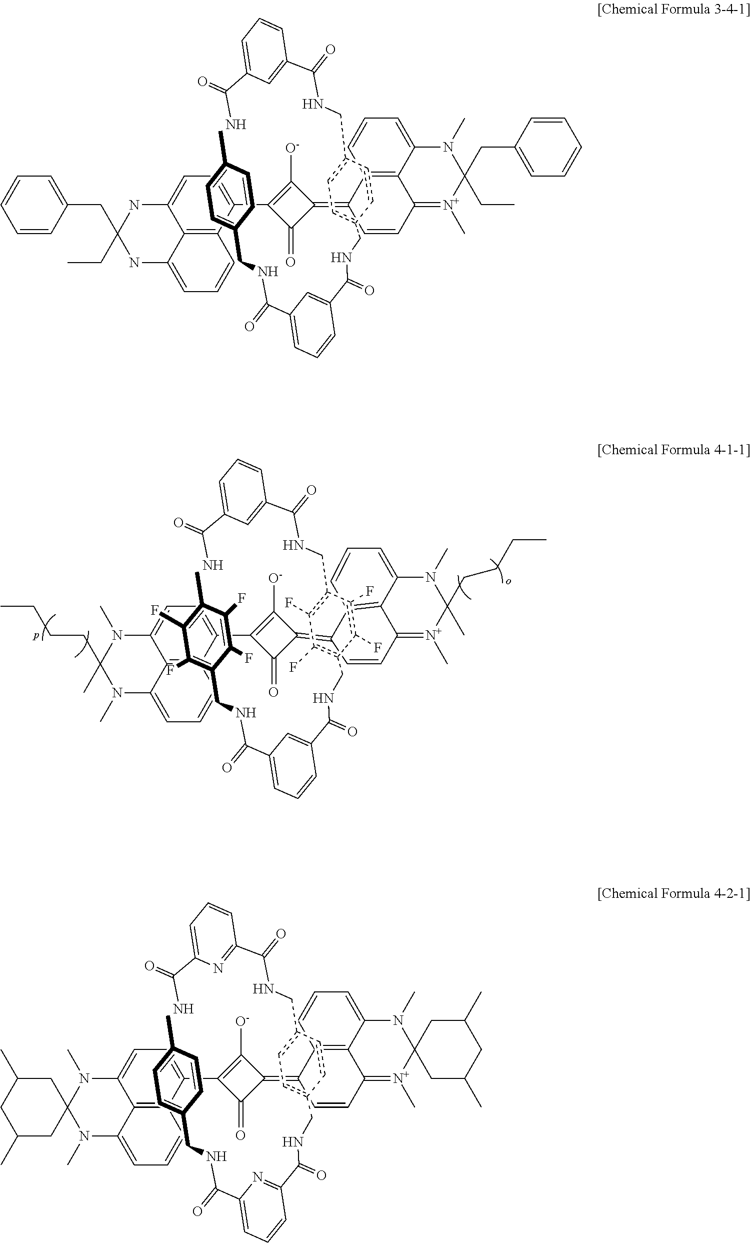

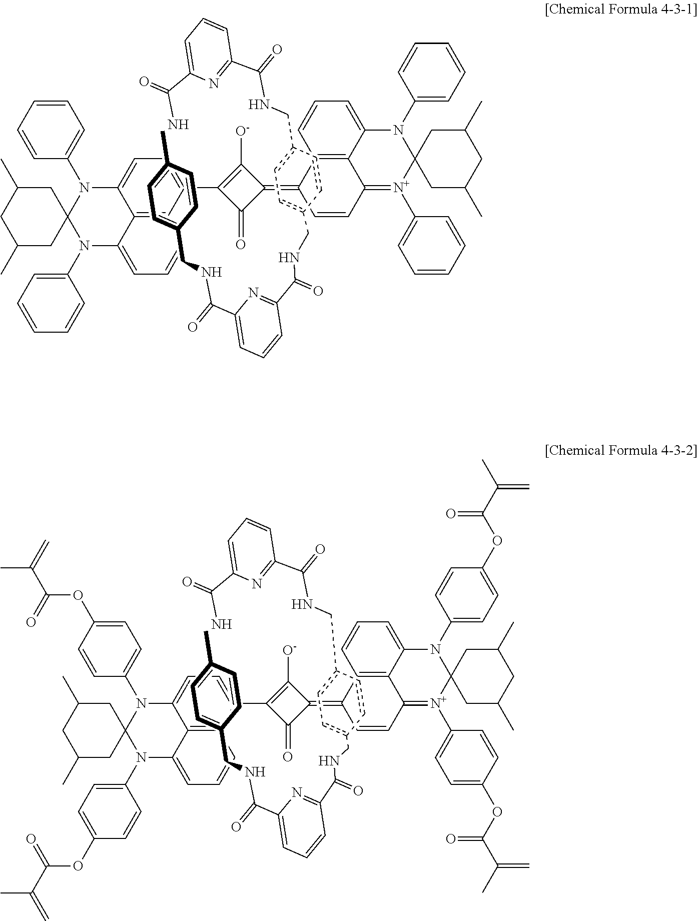

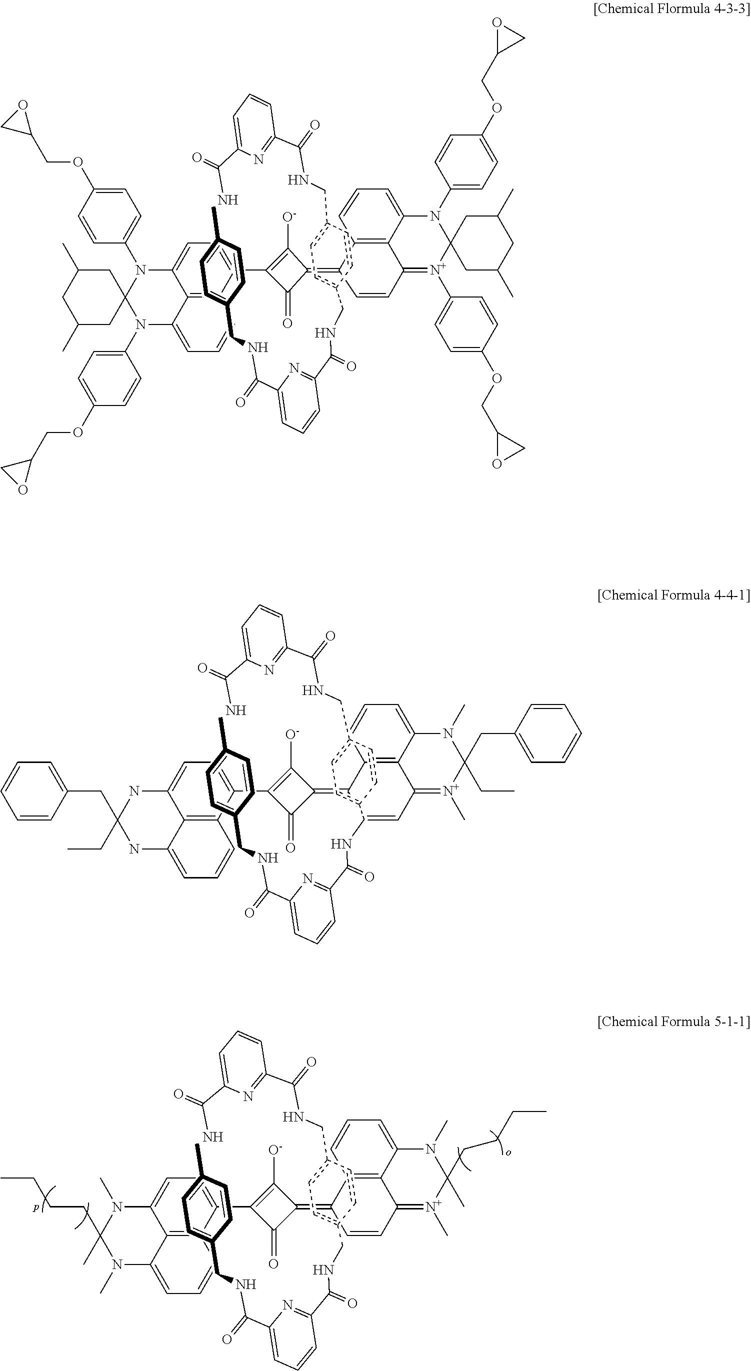

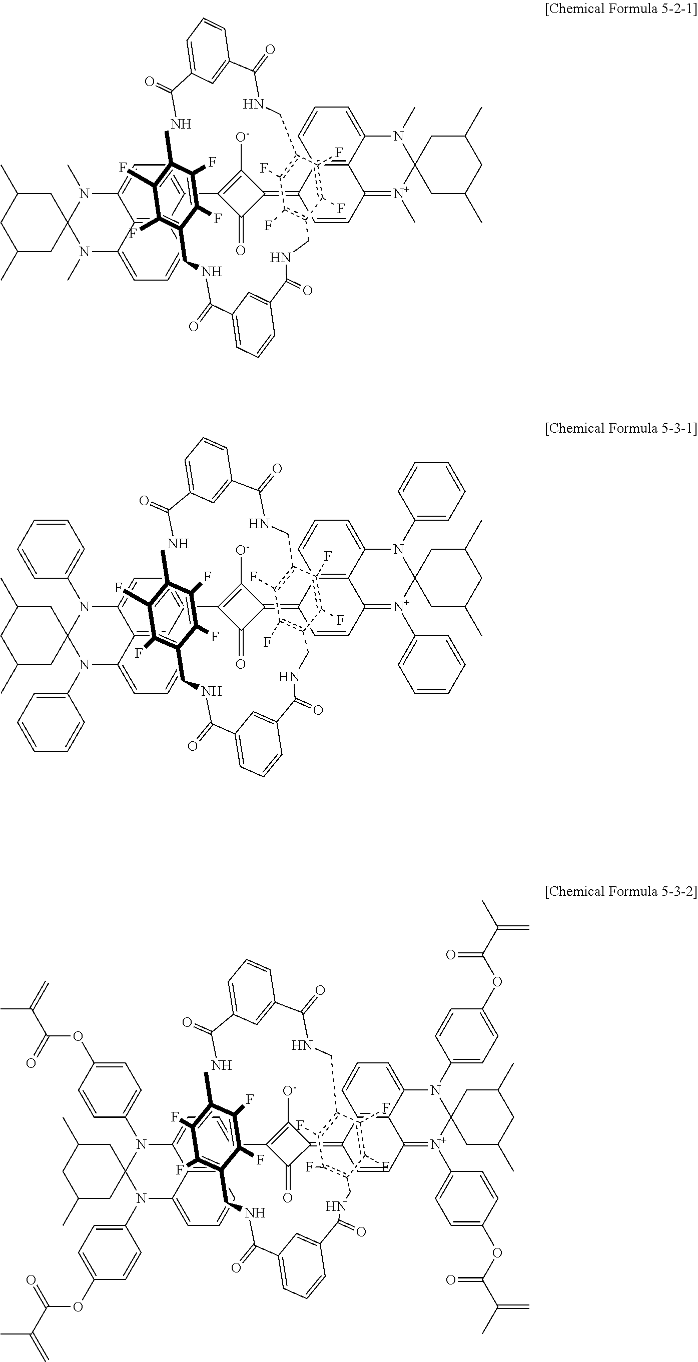

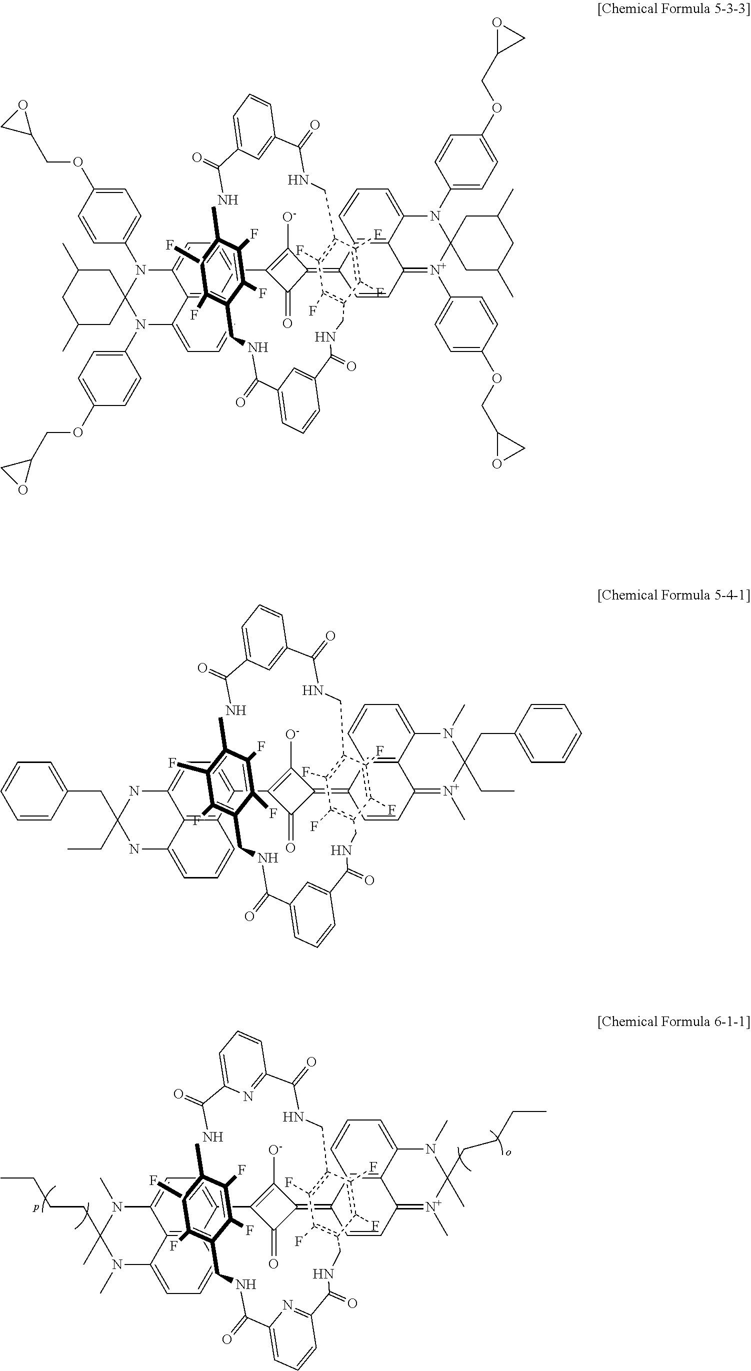

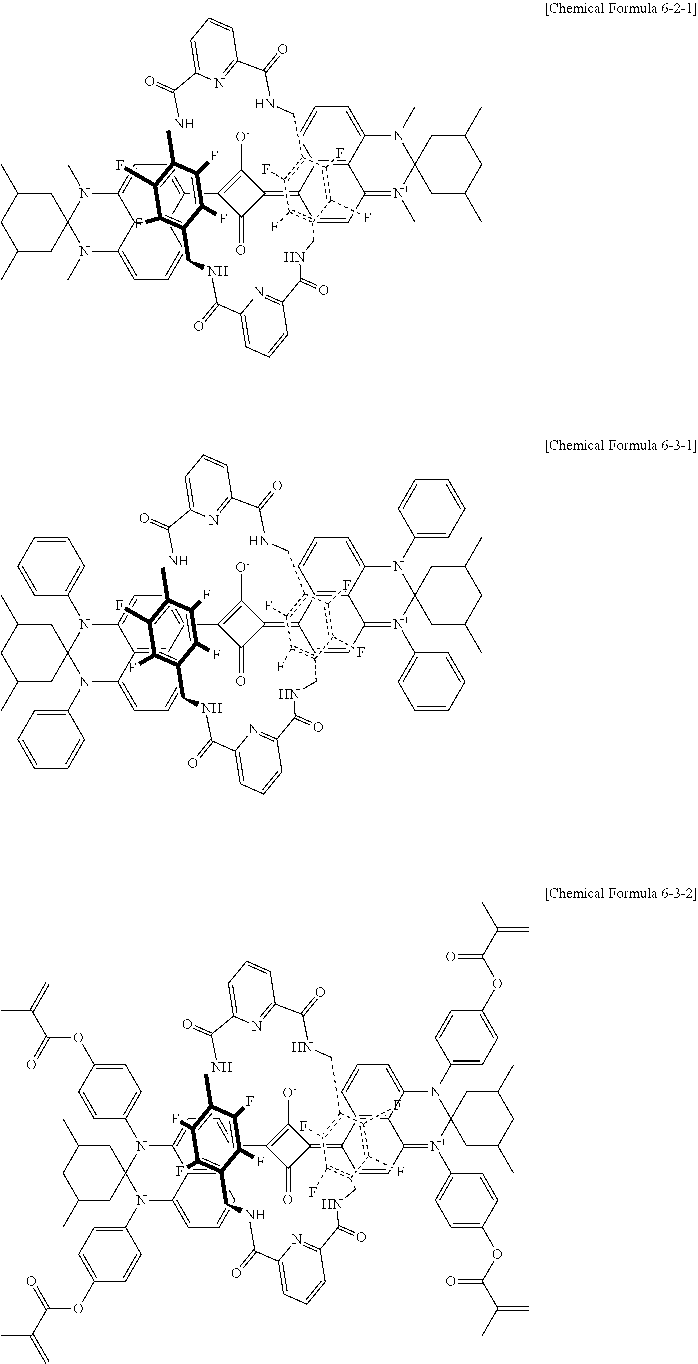

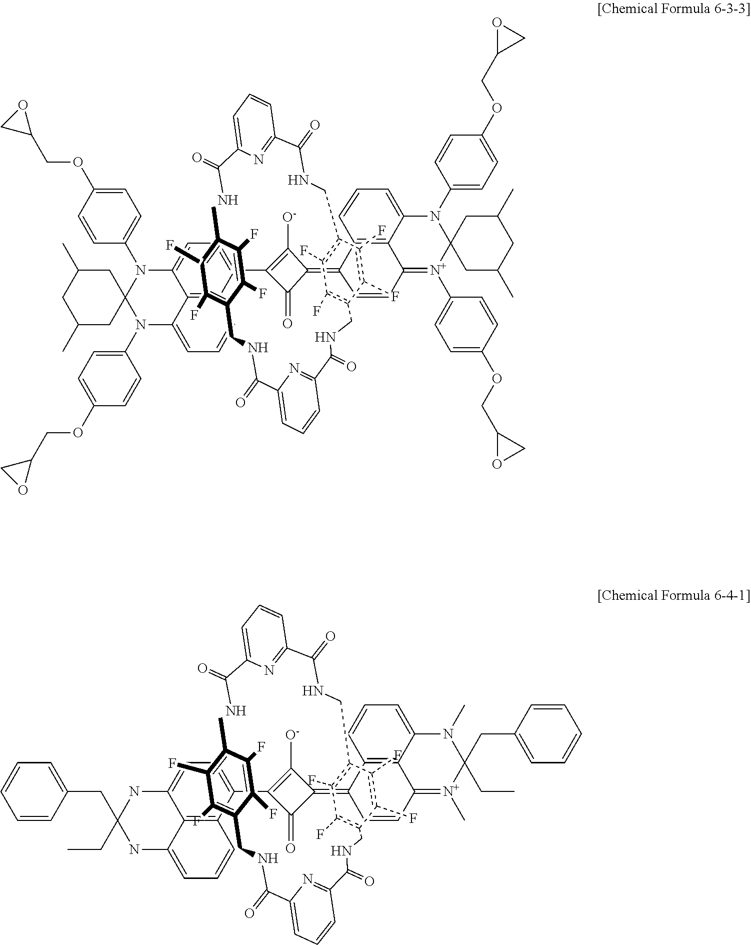

In Chemical Formula 3-1-1, Chemical Formula 4-1-1. Chemical Formula 5-1-1, and Chemical Formula 6-1-1, o and p are each independently an integer of 0 to 5.

The core-shell dye may have a maximum absorption peak at a wavelength of 700 nm to 1,000 nm.

Specifically, when a halogen group is not introduced into the shell represented by Chemical Formula 2, the core-shell dye including the same may have a maximum absorption peak at a wavelength of 700 nm to 850 nm. On the other hand, when a halogen group is introduced into the shell represented by Chemical Formula 2, it may have a maximum absorption peak at a wavelength of 850 nm to 1,000 nm.

That is, when a halogen group is introduced into the shell represented by Chemical Formula 2, the maximum absorption peak of the core-shell compound shifts to a long wavelength region, and matching properties into a near-infrared absorption wavelength band may be exhibited, compared to a case where a halogen group is not introduced.

The core-shell dye may be used alone as a near-infrared absorbing dye, or may be used in combination with an auxiliary dye.

The auxiliary dye may include triarylmethane dyes, anthraquinone dyes, benzylidene dyes, cyanine dyes, phthalocyanine dyes, azaporphyrin dyes, indigo dyes, xanthene dyes, pyridone azo dyes, and the like.

### (Near-Infrared Absorbing Resin Composition)

According to another embodiment, a near-infrared absorbing resin composition includes a compound represented by Chemical Formula 1 or the core-shell dye.

The near-infrared absorbing resin composition may include (A) a colorant (the core-shell dye), (B) a binder resin and (C) a solvent.

Hereinafter, each component is described in detail.

### (A) Colorant

The colorant may include the core-shell dye, and the core-shell dye is described above.

The colorant may further include a pigment in addition to the core-shell dye.

The pigment may include a green pigment, a blue pigment, a red pigment, a purple pigment, a yellow pigment, a black pigment, and the like.

The red pigment may include C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89 and the like, within the color index and these may be used alone or in combination of two or more, but are not necessarily limited thereto.

The purple pigment may include C.I. Violet Pigment 23 (V.23), C.I. Violet Pigment“29, Dioxazine Violet, First Violet B, Methyl Violet Lake, Indanthrene Brilliant Violet,” and the like within the color index, and these may be used alone or in combination of two or more, but are not necessarily limited thereto.

The green pigment may include C.I. Green Pigment 7, C.I. Green Pigment 36, C.I. Green Pigment 58, C.I. Green Pigment 59 and the like within the color index, and these may be used alone or in combination of two or more, but are not necessarily limited thereto.

The blue pigment may include copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16, and the like within the color index, and these may be used alone or in combination of two or more, but are not necessarily limited thereto.

The yellow pigment may include isoindoline-based pigments such as C.I. Yellow Pigment 185, C.I. Yellow Pigment 139, quinophthalone pigments such as C.I. Yellow Pigment 138, nickel complex pigments such as C.I. Yellow Pigment 150, within the color index and these may be used alone or in combination of two or more, but are not necessarily limited thereto.

The black pigment may include aniline black, perylene black, titanium black, carbon black, and the like, within the color index, and these may be used alone or in combination of two or more, but are not necessarily limited thereto.

The pigments may be used alone or in combination of two or more thereof. For example, the pigment may include a blue pigment, a purple pigment, or a mixture thereof.

The pigment may be included in the near-infrared absorbing resin composition in the form of a dispersion. The pigment dispersion may be composed of the pigment, a solvent, a dispersant, and a dispersion resin.

The solvent may be ethylene glycol acetate, ethyl cellosolve, propylene glycol methyl ether acetate, ethyl lactate, polyethylene glycol, cyclohexanone, propylene glycol methyl ether, etc., and among these, propylene glycol methyl ether acetate may be preferably used.

The dispersant helps the pigment to be uniformly dispersed in the dispersion, and nonionic, anionic or cationic dispersants may be used. Specifically, polyalkylene glycol or its ester, polyoxy alkylene, a polyhydric alcohol ester alkylene oxide adduct, an alcohol alkylene oxide adduct, a sulfonic acid ester, a sulfonic acid salt, a carboxylic acid ester, a carboxylic acid salt, an alkyl amide alkylene oxide adduct, an alkylamine, etc. may be used, and these may be used alone or in combination of two or more.

As the dispersion resin, an acrylic resin including a carboxyl group may be used, which may improve the stability of the pigment dispersion as well as the patternability of the pixel.

When the core-shell dye and the pigment are mixed and used, they may be used in a weight ratio of 1:9 to 9:1, specifically, a weight ratio of 3:7 to 7:3. When mixing in the above weight ratio range, chemical resistance, durability, and maximum absorption wavelength may be controlled in an appropriate range, and high luminance and contrast ratio may be exhibited in a desired color coordinate.

The core-shell dye may be included in an amount of 0.5 wt % to 10 wt % based on the total amount of the near-infrared absorbing resin composition. When the core-shell dye is used within the above range, chemical resistance, durability, and maximum absorption wavelength may be controlled in an appropriate range, and high luminance and contrast ratio may be exhibited in a desired color coordinate. For example, it may be included in an amount of 0.5 wt % to 5 wt %, and even if the amount of dye is reduced in this way, chemical resistance, durability, and maximum absorption wavelength may be controlled in an appropriate range.

### (B) Binder Resin

The binder resin may be an organic binder, specifically an acrylic binder. For example, the acrylic binder may be a curable binder, and may include, for example, a thermosetting binder, a photocurable binder, or a combination thereof.

The organic binder may be, for example, methyl cellulose, ethyl cellulose, hydroxypropyl methyl cellulose (HPMC), hydroxylpropyl cellulose (HPC), xanthan gum, polyvinyl alcohol (PVA), polyvinyl pyrrolidone (PVP), carboxy methyl cellulose, hydroxyl ethyl cellulose, or a combination thereof, but is limited thereto.

Methacrylic acid/benzyl methacrylate copolymers such as the examples described later may be used, and a copolymerization ratio thereof may be 1:99 to 99:1, specifically 10:90 to 20:80 as a weight ratio of methacrylic acid: benzyl methacrylate.

### (C) Solvent

The solvent is not particularly limited, but specifically, for example, alcohols such as methanol and ethanol; ethers such as dichloroethyl ether, n-butyl ether, diisoamyl ether, methylphenyl ether, tetrahydrofuran, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; hydroxyacetic acid alkyl esters such as methyl hydroxyacetate, ethyl hydroxyacetate, butyl hydroxyacetate, and the like; acetic acid alkoxyalkyl esters such as methoxymethyl acetate, methoxyethyl acetate, methoxybutyl acetate, ethoxymethyl acetate, ethoxyethyl acetate, and the like; 3-hydroxypropionic acid alkyl esters such as methyl 3-hydroxypropionate, ethyl 3-hydroxypropionate, and the like; 3-alkoxypropionic acid alkyl esters such as methyl 3-methoxypropionate, ethyl 3-methoxypropionate, ethyl 3-ethoxypropionate, methyl 3-ethoxypropionate, and the like; 2-hydroxypropionic acid alkyl esters such as methyl 2-hydroxypropionate, ethyl 2-hydroxypropionate, propyl 2-hydroxypropionate, and the like; 2-alkoxypropionic acid alkyl esters such as methyl 2-methoxypropionate, ethyl 2-methoxypropionate, ethyl 2-ethoxypropionate, methyl 2-ethoxypropionate, and the like; 2-hydroxy-2-methylpropionic acid alkyl esters such as methyl 2-hydroxy-2-methylpropionate, ethyl 2-hydroxy-2-methylpropionate, and the like; 2-alkoxy-2-methylpropionic acid alkyl esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; or ketonate esters such as ethyl pyruvate, and the like, and may be additionally N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like, and they may be used alone or as a mixture of two or more.

Considering miscibility and reactivity, the solvent may be glycol ethers such as ethylene glycol monoethyl ether, and the like; ethylene glycol alkylether acetates such as ethyl cellosolve acetate, and the like; esters such as 2-hydroxyethyl propionate, and the like; diethylene glycols such as diethylene glycol monomethyl ether, and the like; propylene glycol alkylether acetates such as propylene glycol monomethylether acetate, propylene glycol propylether acetate, and the like.

The solvent may be included in a balance amount, for example 20 wt % to 90 wt % based on the total amount of the near-infrared absorbing resin composition. When the solvent is included within the above range, the near-infrared absorbing resin composition has excellent applicability, and excellent flatness may be maintained in a film having a thickness of 3 μm or more.

### (D) Other Additives

The near-infrared absorbing resin composition may further include other additives such as malonic acid; 3-amino-1,2-propanediol; a silane-based coupling agent including a vinyl group or a (meth)acryloxy group; a leveling agent; a fluorine-based surfactant; a radical polymerization initiator, and the like in order to prevent stains or spots during the coating, to adjust leveling, or to prevent pattern residue due to non-development.

The near-infrared absorbing resin composition may further include an epoxy compound in order to improve close-contacting properties with a substrate.

Examples of the epoxy compound may include a phenol novolac epoxy compound, a tetramethyl biphenyl epoxy compound, a bisphenol A epoxy compound, an alicyclic epoxy compound, or a combination thereof.

A use amount of the additive may be controlled depending on desired properties.

Another embodiment provides a near-infrared absorbing film manufactured using the aforementioned near-infrared absorbing resin composition. A manufacturing method of the near-infrared absorbing film is as follows.

The aforementioned near-infrared absorbing resin composition may be coated on a polymer film using an appropriate method such as bar coating, spin coating, or slit coating. Thereafter, the film may be dried and cured by heat or light to finally obtain a near-infrared absorbing film.

The near-infrared absorbing film may effectively absorb light in a near-infrared region regardless of an incident direction and thus effectively absorb and block incident light in the near-infrared region from a side direction, thereby reducing or preventing signal distortion caused by light in a visible region caused by the incident light in near-infrared region from the side direction.

Another embodiment provides an optical filter including the aforementioned near-infrared absorbing film. In addition, another embodiment provides a CMOS image sensor including the aforementioned optical filter.

When the optical filter including the near-infrared absorption film is applied to a CMOS image sensor, optical distortion caused by near-infrared rays may be reduced or prevented.

Hereinafter, the present invention is illustrated in more detail with reference to examples. These examples, however, are not in any sense to be interpreted as limiting the scope of the invention.

### Synthesis Examples

### Synthesis Example 1: Synthesis of Core-shell Dye Represented by Chemical Formula 3-1-1

### (1) Synthesis of Compound A-1

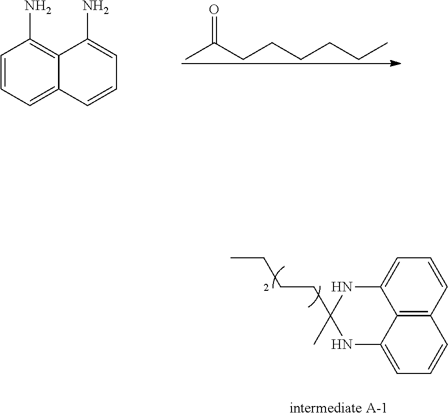

1,8-diaminonaphthalene (6 mmol), 2-octanone (6 mmol), p-toluenesulfonic acid (0.6 mmol), and toluene were put in a round flask and refluxed. After about 15 hours, the resultant was several times washed with ethyl acetate (EA) and water. Subsequently, the resultant was distilled under a reduced pressure distillation and separated through column chromatography, obtaining Compound A-1 as an intermediate.

### (2) Synthesis of Compound A-2

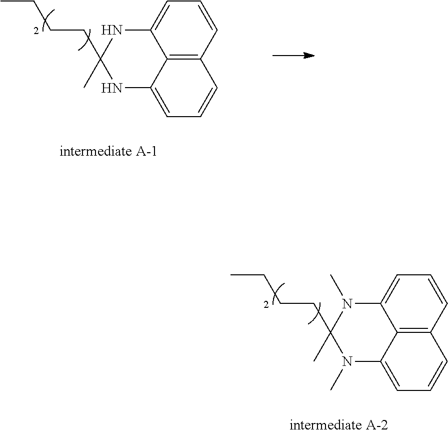

Compound A-1 (5 mmol), sodium bicarbonate (25 mmol), iodo metane (12.5 mmol), and DMF were put in a round flask and then, stirred at 50° C. for 4 hours, and several times washed with ethyl acetate (EA) and water. The resultant was distilled under a reduced pressure and separated through column chromatography, obtaining Compound A-2.

### (3) Synthesis of Compound A-3

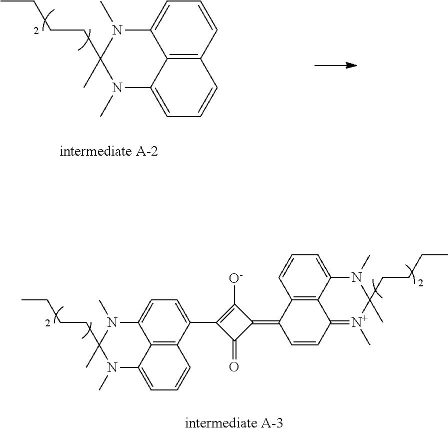

Compound A-2 (10 mmol) and 3,4-dihydroxy-cyclobut-3-ene-1,2-dione (5 mmol) were added to toluene and butanol and then, refluxed, and a Dean-stark distillation device was used to remove water produced therefrom. The reactant was stirred for 12 hours, distilled under a reduced pressure, and purified through column chromatography, obtaining Compound A-3 as an intermediate.

### (3) Synthesis of Core-shell Dye Represented by Chemical Formula 3-1-1

After dissolving Compound A-3 (5 mmol) in a chloroform solvent, Isophthaloyl chloride (20 mmol) and p-xylylenediamine (20 mmol) were dissolved in chloroform and then, simultaneously added dropwise thereto at room temperature for 5 hours. After 12 hours, a core-shell dye represented by Chemical Formula 3-1-1 was obtained by distillation under a reduced pressure and separation through column chromatography.

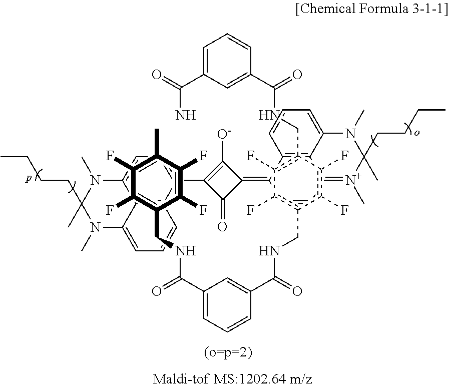

### Synthesis Example 2: Synthesis of Core-shell Dye Represented by Chemical Formula 4-1-1

After dissolving Compound A-3 (5 mmol) in a chloroform solvent, isophthaloyl chloride (20 mmol) and tetrafluoro-p-xylylenediamine (20 mmol) were dissolved in chloroform and then, simultaneously added dropwise thereto at room temperature for 5 hours. After 12 hours, a core-shell dye represented by Chemical Formula 4-1-1 was obtained by distillation under a reduced pressure and separation through column chromatography.

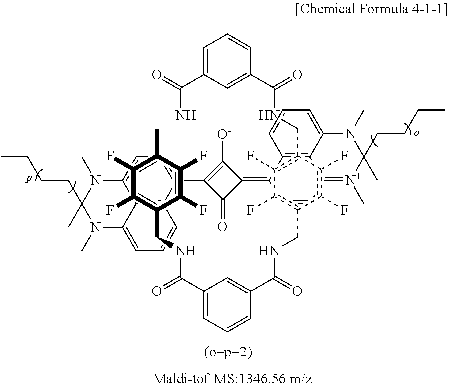

### Synthesis Example 3: Synthesis of Core-shell Dye Represented by Chemical Formula 5-1-1

After dissolving Compound A-3 (5 mmol) in a chloroform solvent, pyridine-2,6-dicarbonyl dichloride (20 mmol) and p-xylylenediamine (20 mmol) were dissolved in chloroform and simultaneously added dropwise thereto at room temperature for 5 hours. After 12 hours, a core-shell dye represented by Chemical Formula 5-1-1 was obtained by distillation under a reduced pressure and separation through column chromatography.

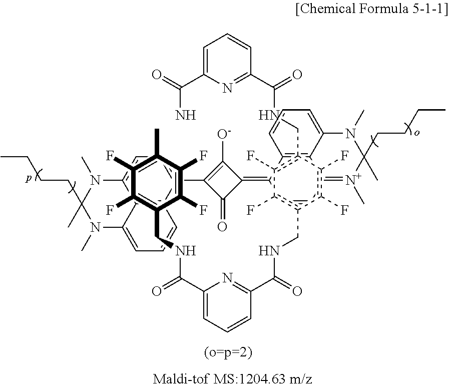

### Synthesis Example 4: Synthesis of Core-shell Dye Represented by Chemical Formula 6-1-1

After dissolving Compound A-3 (5 mmol) in a chloroform solvent, pyridine-2,6-dicarbonyl dichloride (20 mmol) and tetrafluoro-p-xylylenediamine (20 mmol) were dissolved in chloroform and then, simultaneously added dropwise thereto at room temperature for 5 hours. After 12 hours, a core-shell dye represented by Chemical Formula 6-1-1 was obtained by distillation under a reduced pressure and separation through column chromatography.

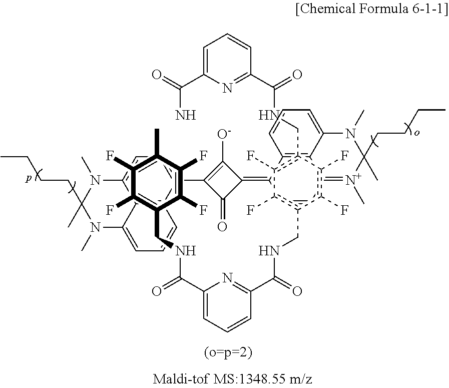

### Synthesis Example 5: Synthesis of Core-shell Dye Represented by Chemical Formula 6-2-1

### (1) Synthesis of Compound B-1

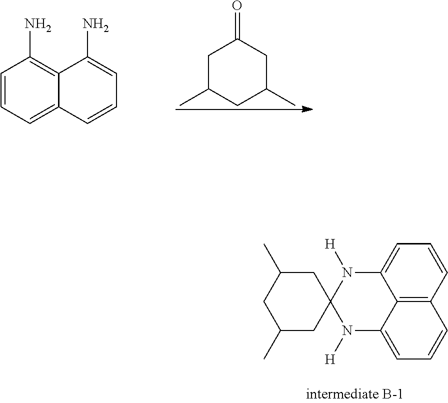

Compound B-1 was synthesized in the same manner as the synthesis method of Compound A-1 except that the 2-octanone was changed into 3,4-dimethylcyclohexanone.

### (2) Synthesis of Compound B-2

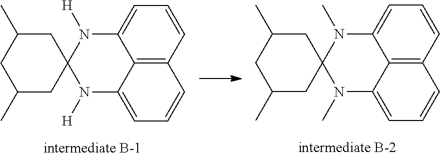 [SMILES: CC1CC(C)CC2(C1)Nc1cccc3cccc(c13)N2 ; CC1CC(C)CC2(C1)N(C)c1cccc3cccc(c13)N2C]

Compound B-2 was synthesized in the same manner as the synthesis method of Compound A-2 except that Compound A-1 was changed into Compound B-1.

### (3) Synthesis of Compound B-3

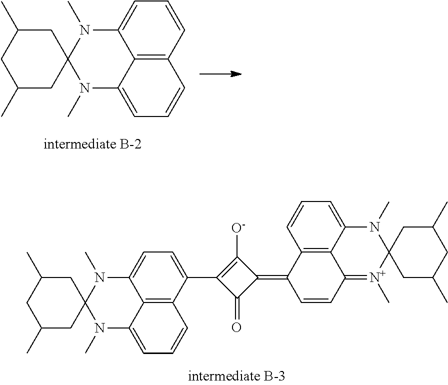 [SMILES: CC1CC(C)CC2(C1)N(C)c1cccc3cccc(c13)N2C ; CC1CC(C)CC2(C1)N(C)c1cccc3c(C4=C([O-])/C(=c5/ccc6c7c(cccc57)N(C)C5(CC(C)CC(C)C5)[N+]=6C)C4=O)ccc(c13)N2C]

Compound B-3 was synthesized in the same manner as the synthesis method of Compound A-3 except that Compound A-2 was changed into Compound B-2.

### (4) Synthesis of Core-shell Dye Represented by Chemical Formula 6-2-1

After dissolving Compound B-3 (5 mmol) in a chloroform solvent, pyridine-2,6-dicarbonyl dichloride (20 mmol) and tetrafluoro-p-xylylenediamine (20 mmol) were dissolved in chloroform and simultaneously added dropwise thereto at room temperature for 5 hours. After 12 hours, a core-shell dye represented by Chemical Formula 6-2-1 was obtained by distillation under a reduced pressure and separation through column chromatography.

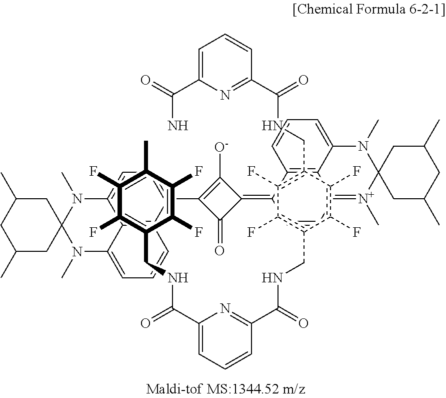

### Synthesis Example 6: Synthesis of Core-shell Dye Represented by Chemical Formula 6-3-1

### (1) Synthesis of Compound C-1

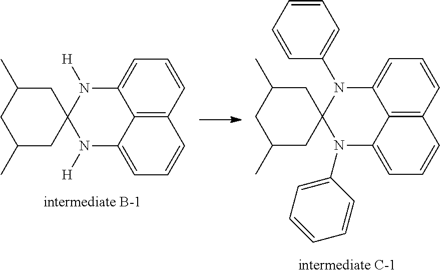 [SMILES: CC1CC(C)CC2(C1)Nc1cccc3cccc(c13)N2 ; CC1CC(C)CC2(C1)N(c1ccccc1)c1cccc3cccc(c13)N2c1ccccc1]

Compound C-1 was synthesized in the same manner as the synthesis method of Compound A-2 except that the iodomethane was changed into iodobenzene.

### (2) Synthesis of Compound C-2

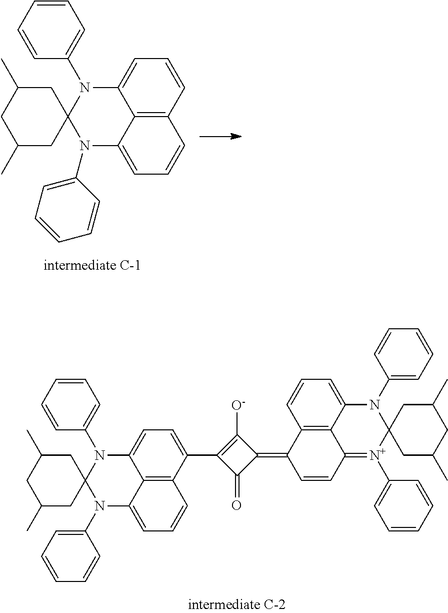 [SMILES: CC1CC(C)CC2(C1)N(c1ccccc1)c1cccc3cccc(c13)N2c1ccccc1 ; CC1CC(C)CC2(C1)N(c1ccccc1)c1cccc3c(C4=C([O-])/C(=c5/ccc6c7c(cccc57)N(c5ccccc5)C5(CC(C)CC(C)C5)[N+]=6c5ccccc5)C4=O)ccc(c13)N2c1ccccc1]

Compound C-2 was synthesized in the same manner as the synthesis method of Compound A-3 except that Compound A-2 was changed into Compound C-1.

### (4) Synthesis of Core-shell Dye Represented by Chemical Formula 6-3-1

After dissolving Compound C-2 (5 mmol) in a chloroform solvent, pyridine-2,6-dicarbonyl dichloride (20 mmol) and tetrafluoro-p-xylylenediamine (20 mmol) were dissolved in chloroform and simultaneously added dropwise thereto at room temperature for 5 hours. After 12 hours, a core-shell dye represented by Chemical Formula 6-3-1 was obtained by distillation under a reduced pressure and separation through column chromatography.

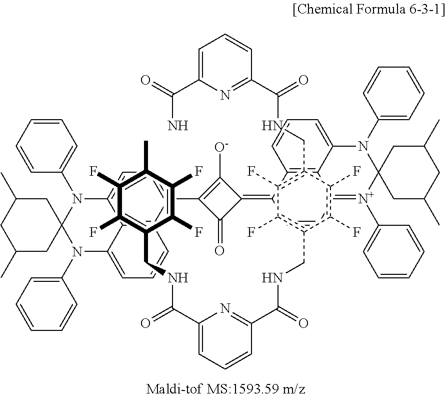

### Synthesis Example 7: Synthesis of Core-shell Dye Represented by Chemical Formula 6-3-2

### (1) Synthesis of Compound D-1

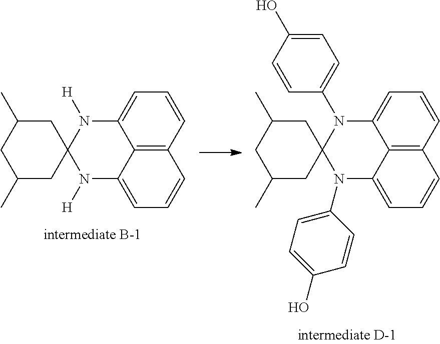 [SMILES: CC1CC(C)CC2(C1)Nc1cccc3cccc(c13)N2 ; CC1CC(C)CC2(C1)N(c1ccc(O)cc1)c1cccc3cccc(c13)N2c1ccc(O)cc1]

Compound D-1 was synthesized in the same manner as the synthesis method of Compound A-2 except that the iodomethane was changed into 4-iodophenol.

### (2) Synthesis of Compound D-2

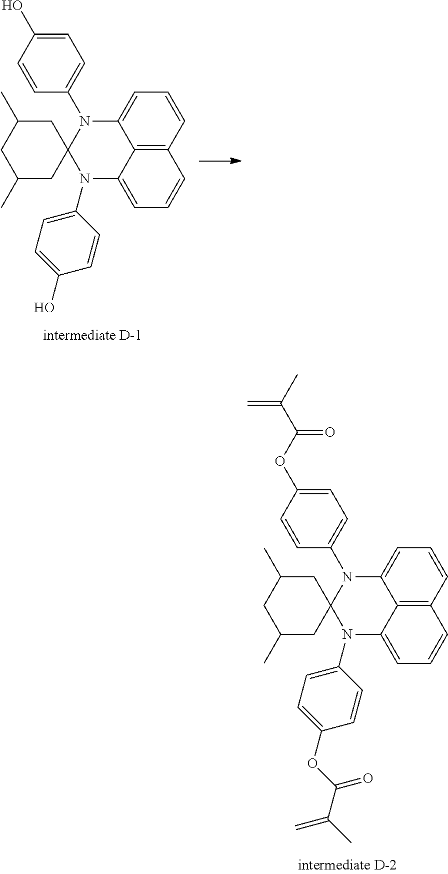 [SMILES: CC1CC(C)CC2(C1)N(c1ccc(O)cc1)c1cccc3cccc(c13)N2c1ccc(O)cc1 ; C=C(C)C(=O)Oc1ccc(N2c3cccc4cccc(c34)N(c3ccc(OC(=O)C(=C)C)cc3)C23CC(C)CC(C)C3)cc1]

After dissolving Compound D-1 (20 mmol) in a dichloromethane solvent, triethylamine (50 mmol) was added thereto and then, cooled with an N₂ charge and in an ice bath. After the cooling, methacryloyl chloride (45 mmol) was added dropwise thereto. The obtained mixture was stirred at 0° C. to room temperature for about 2 hours. After 2 hours, extraction with MC was conducted.

Compound D-2 was obtained by distillation under a reduced pressure and separation through column chromatography.

### (3) Synthesis of Compound D-3

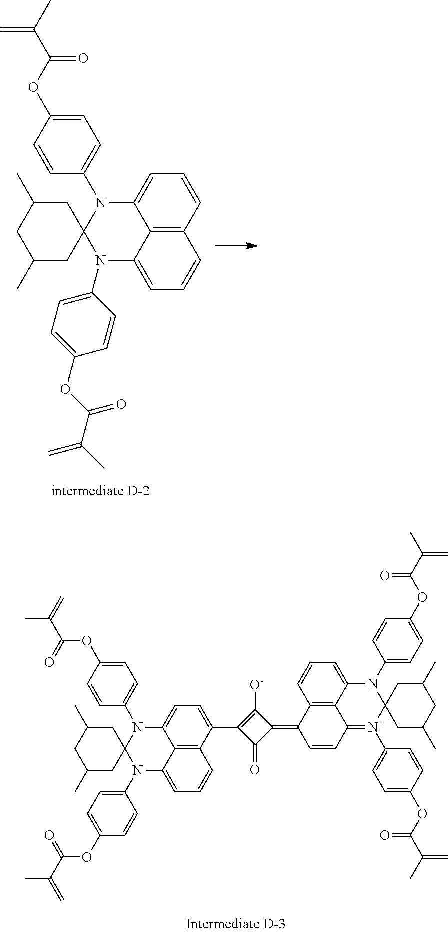 [SMILES: C=C(C)C(=O)Oc1ccc(N2c3cccc4cccc(c34)N(c3ccc(OC(=O)C(=C)C)cc3)C23CC(C)CC(C)C3)cc1 ; C=C(C)C(=O)Oc1ccc(N2c3cccc4c(C5=C([O-])/C(=c6/ccc7c8c(cccc68)N(c6ccc(OC(=O)C(=C)C)cc6)C6(CC(C)CC(C)C6)[N+]=7c6ccc(OC(=O)C(=C)C)cc6)C5=O)ccc(c34)N(c3ccc(OC(=O)C(=C)C)cc3)C23CC(C)CC(C)C3)cc1]

Compound D-3 was synthesized in the same manner as in the synthesis method of Compound A-3 except that Compound A-2 was changed into Compound D-3.

### (4) Synthesis of Core-shell Dye Represented by Chemical Formula 6-3-2

After dissolving Compound D-3 (5 mmol) in a chloroform solvent, pyridine-2,6-dicarbonyl dichloride (20 mmol) and tetrafluoro-p-xylylenediamine (20 mmol) were dissolved in chloroform and simultaneously added dropwise thereto at room temperature for 5 hours. After 12 hours, a core-shell dye represented by Chemical Formula 6-3-2 was obtained by distillation under a reduced pressure and separation through column chromatography.

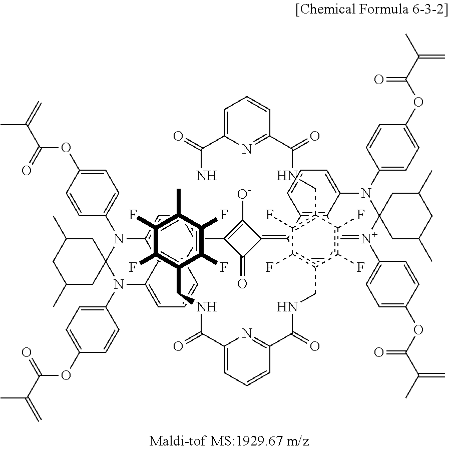

### Synthesis Example 8: Synthesis of Core-shell Dye Represented by Chemical Formula 6-3-3

### (1) Synthesis of Compound E-1

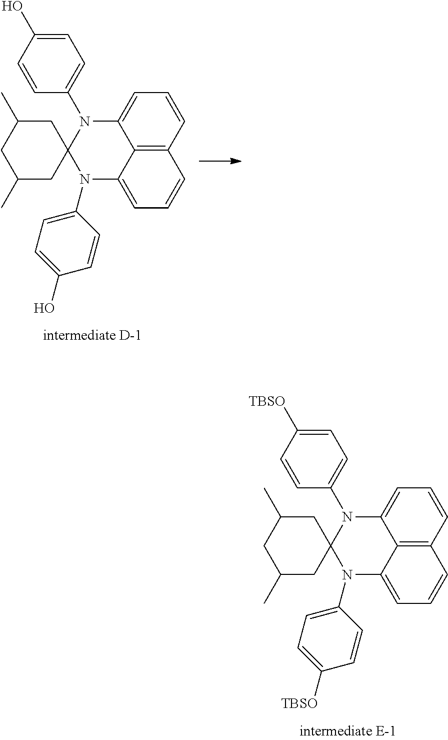 [SMILES: CC1CC(C)CC2(C1)N(c1ccc(O)cc1)c1cccc3cccc(c13)N2c1ccc(O)cc1 ; CC1CC(C)CC2(C1)N(c1ccc(O[Si](C)(C)C(C)(C)C)cc1)c1cccc3cccc(c13)N2c1ccc(O[Si](C)(C)C(C)(C)C)cc1]

Compound D-1 (10 mmol) was dissolved in a DMF solvent, and imidazole (30 mmol) was added thereto and then, stirred at room temperature for 30 minutes. Tert-butyldimethylsilyl chloride (25 mmol) was added thereto and then, stirred for 3 hours at 40° C. Compound E-1 as an intermediate was obtained by several times washing with ethyl acetate/water, distillation under a reduced pressure, and separation through column chromatography.

### (2) Synthesis of Compound E-2

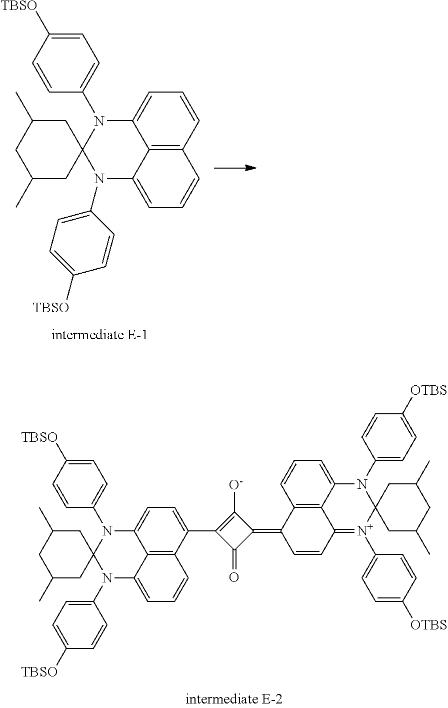 [SMILES: CC1CC(C)CC2(C1)N(c1ccc(O[Si](C)(C)C(C)(C)C)cc1)c1cccc3cccc(c13)N2c1ccc(O[Si](C)(C)C(C)(C)C)cc1 ; CC1CC(C)CC2(C1)N(c1ccc(O[Si](C)(C)C(C)(C)C)cc1)c1cccc3c(C4=C([O-])/C(=c5/ccc6c7c(cccc57)N(c5ccc(O[Si](C)(C)C(C)(C)C)cc5)C5(CC(C)CC(C)C5)[N+]=6c5ccc(O[Si](C)(C)C(C)(C)C)cc5)C4=O)ccc(c13)N2c1ccc(O[Si](C)(C)C(C)(C)C)cc1]

Compound E-2 was synthesized in the same manner as in the synthesis method of Compound A-3 except that Compound A-2 was changed into Compound E-1.

### (3) Synthesis of Compound B-3

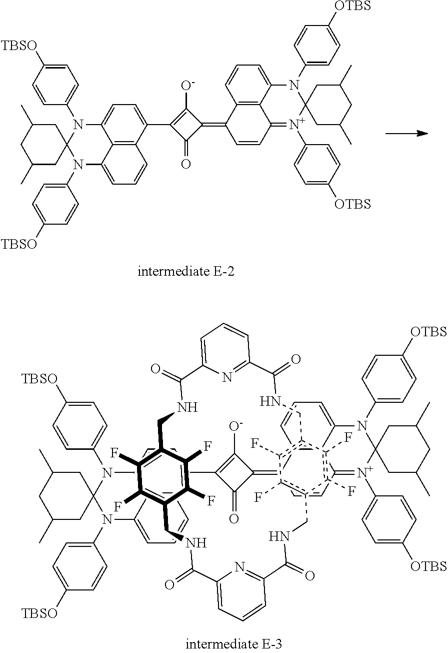

After dissolving Compound E-2 (5 mmol) in a chloroform solvent, pyridine-2,6-dicarbonyl dichloride (20 mmol) and tetrafluoro-p-xylylenediamine (20 mmol) were dissolved in chloroform and simultaneously added dropwise thereto at room temperature for 5 hours. After 12 hours, Compound E-3 as an intermediate was obtained by distillation under a reduced pressure and separation through column chromatography.

### (4) Synthesis of Compound E-4

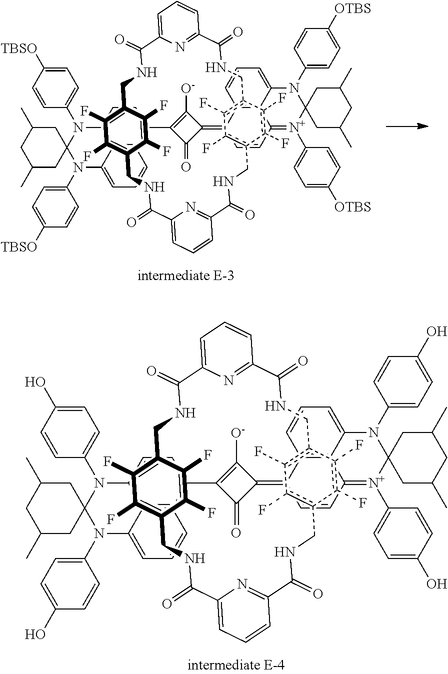

Compound E-3 (5 mmol) was dissolved in a tetrahydrofuran solvent, and tetrabutylammonium fluoride (11 mmol) was added thereto at room temperature. After 30 minutes, Compound E-4 as an intermediate was obtained by separation through column chromatography.

### (4) Synthesis of Core-shell Dye Represented by Chemical Formula 6-3-3

Compound E-4 (5 mmol), KOH (25 mmol), and epichlorohydrin (50 mmol) were reacted in 25 mL of a dimethyl sulfoxide solvent for 2 hours and then, extracted with a 10% NH₄Cl aqueous solution and ethyl acetate. A core-shell dye represented by Chemical Formula 6-3-3 was obtained by separation through column chromatography.

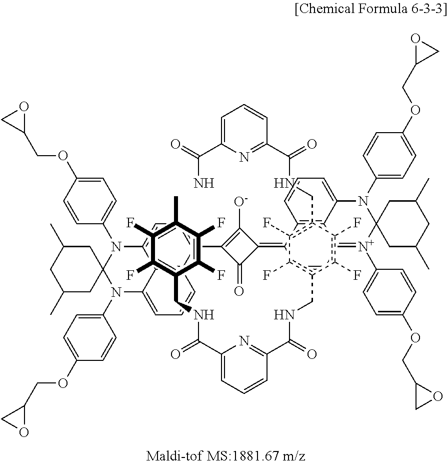

### Synthesis Example 9: Synthesis of Core-shell Dye Represented by Chemical Formula 6-4-1

### (1) Synthesis of Compound F-1

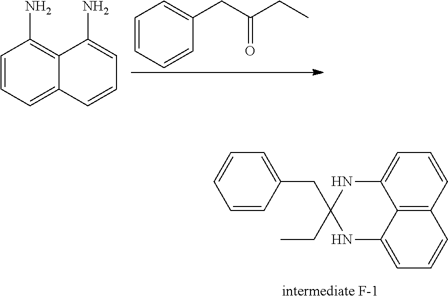

1,8-diaminonaphthalene (6 mmol), 1-phenyl-2butanone (6 mmol), p-toluene sulfonic acid (0.6 mmol), and toluene were put in a round flask and then, refluxed. After about 15 hours, the resultant is several times washed with ethyl acetate (EA) and water. Compound F-1 as an intermediate was obtained by distillation under a reduced pressure and separation through column chromatography.

### (2) Synthesis of Compound F-2

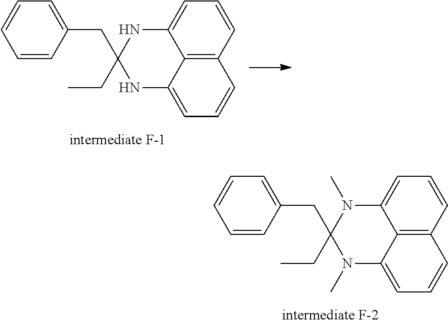 [SMILES: CCC1(Cc2ccccc2)Nc2cccc3cccc(c23)N1 ; CCC1(Cc2ccccc2)N(C)c2cccc3cccc(c23)N1C]

Compound F-2 was synthesized in the same manner as in the synthesis method of Compound A-2 except that Compound A-1 was changed into Compound F-1.

### (3) Synthesis of Compound F-3

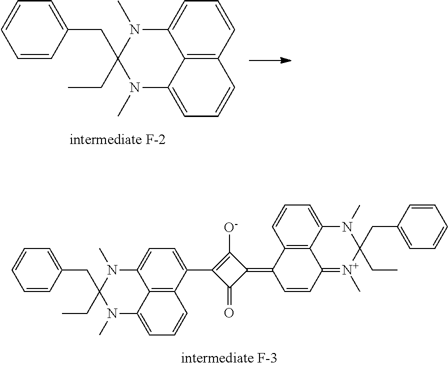 [SMILES: CCC1(Cc2ccccc2)N(C)c2cccc3cccc(c23)N1C ; CCC1(Cc2ccccc2)N(C)c2cccc3c(C4=C([O-])/C(=c5/ccc6c7c(cccc57)N(C)C(CC)(Cc5ccccc5)[N+]=6C)C4=O)ccc(c23)N1C]

Compound F-3 was synthesized in the same manner as in the synthesis method of Compound A-3 except that Compound A-2 was changed into Compound F-2.

### (4) Synthesis of Core-shell Dye Represented by Chemical Formula 6-4-1

After dissolving Compound F-2 (5 mmol) in a chloroform solvent, pyridine-2,6-dicarbonyl dichloride (20 mmol) and tetrafluoro-p-xylylenediamine (20 mmol) were dissolved in chloroform and simultaneously added dropwise thereto at room temperature for 5 hours. After 12 hours, a core-shell dye represented by Chemical Formula 6-4-1 was obtained by distillation under a reduced pressure and separation through column chromatography.

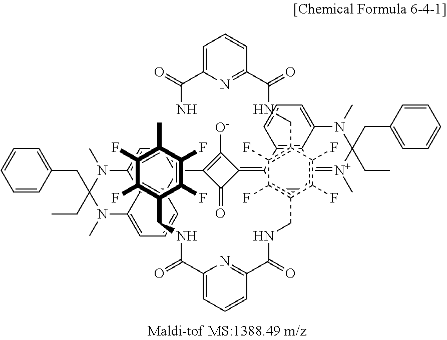

### Comparative Synthesis Example 1: Synthesis of Core-only Dye Represented by Chemical Formula G

### (1) Synthesis of Compound G-1

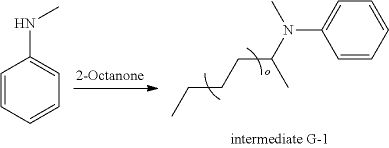

N-methylaniline (6 mmol), 2-octanone (6 mmol), p-toluenesulfonic acid (0.6 mmol), and toluene were put in a round flask and refluxed. After 15 hours, the resultant was several times washed with ethyl acetate (EA) and water. Compound G-1 as an intermediate was obtained by distillation under a reduced pressure and separation through column chromatography.

(2) Synthesis of Core-only Dye represented by Chemical Formula G

A core-only dye represented by Chemical Formula G was synthesized in the same manner as in the synthesis method of intermediate A-3 except that Intermediate A-2 was changed into Intermediate G-1.

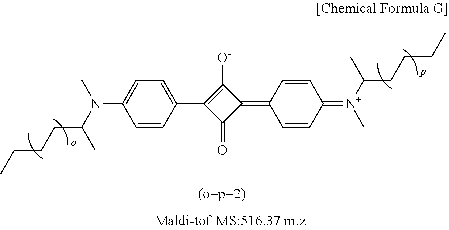

### Comparative Synthesis Example 2: Synthesis of Core-shell Dye Represented by Chemical Formula H

After dissolving Compound A (5 mmol) in a chloroform solvent, Isophthaloyl chloride (20 mmol) and p-xylylenediamine (20 mmol) were dissolved in chloroform and simultaneously added dropwise thereto at room temperature for 5 hours. After 12 hours, a compound represented by Chemical Formula H was obtained by distillation under a reduced pressure and separation through column chromatography.

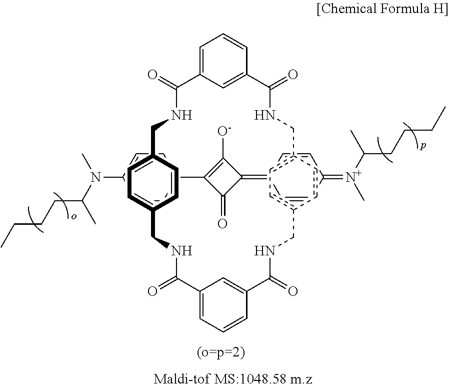

### (Preparation of Near-Infrared Absorbing Resin Composition)

The specifications of components used in the preparation of the near-infrared absorbing resin composition are as follows.

### (A) Colorant

(A-1) Core-shell dye prepared in Synthesis Example 1 (Chemical Formula 3-1-1)
(A-2) Core-shell dye prepared in Synthesis Example 2 (Chemical Formula 4-1-1)
(A-3) Core-shell dye prepared in Synthesis Example (Chemical Formula 5-1-1)
(A-4) Core-shell dye prepared in Synthesis Example 4 (Chemical Formula 6-1-1)
(A-5) Core-shell dye prepared in Synthesis Example 5 (Chemical Formula 6-2-1)
(A-6) Core-shell dye prepared in Synthesis Example 6 (Chemical Formula 6-3-1)
(A-7) Core-shell dye prepared in Synthesis Example 7 (Chemical Formula 6-3-2)
(A-8) Core-shell dye prepared in Synthesis Example 8 (Chemical Formula 6-3-3)
(A-9) Core-shell dye prepared in Synthesis Example 9 (Chemical Formula 6-4-1)
(A-10) Core-shell dye prepared in Comparative Synthesis Example 1 (Chemical Formula G)
(A-11) Core-shell dye prepared in Comparative Synthesis Example 2 (Chemical Formula H)
(A-12) Pigment CI, Pigment green 7

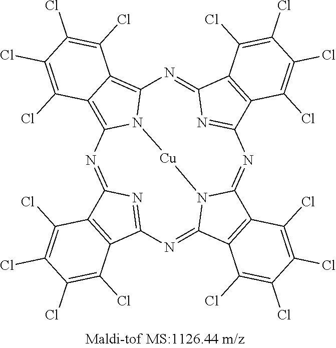

### (B) Binder Resin

Methacrylic acid/benzyl methacrylate copolymer having a weight average molecular weight of 22,000 g/mol (a mixed weight ratio=15 wt %/85 wt %)

### (C) Solvent

(C-1) cyclohexanone
(C-2) propylene glycol methyletheracetate

### Examples 1 to 8 and Comparative Examples 1 to 3

Each of photosensitive resin compositions was prepared by mixing components in compositions shown in Tables 1 and 3. Specifically, the colorant was added to the solvent and then, stirred for 30 minutes, and the binder resin was added thereto and then, stirred for 2 hours at room temperature. The solution was three times filtered to remove impurities, obtaining each near-infrared absorbing resin composition.

TABLE 1
(unit: wt %)

| | | Examples | | | | |
|---|---|---|---|---|---|---|
| | | Solid content (wt %) | 1 | 2 | 3 | 4 |
| (A) Colorant | A-1 | 100 | 2 | — | — | — |
| | A-2 | 100 | — | 2 | — | — |
| | A-3 | 100 | — | — | 2 | — |
| | A-4 | 100 | — | — | — | 2 |
| (B) Binder resin | | 100 | 13 | 13 | 13 | 13 |
| (C) Solvent | C-1 | — | 40 | 40 | 40 | 40 |
| | C-2 | — | 45 | 45 | 45 | 45 |

| | | | | |
|---|---|---|---|---|
| Total | 100 | 100 | 100 | 100 |

TABLE 2
(unit: wt %)

| | | Examples | | | | |
|---|---|---|---|---|---|---|
| | | Solid content (wt %) | 5 | 6 | 7 | 8 |
| (A) Colorant | A-5 | 100 | 2 | — | — | — |
| | A-6 | 100 | — | 2 | — | — |
| | A-7 | 100 | — | — | 2 | — |
| | A-8 | 100 | — | — | — | 2 |
| (B) Binder resin | | 100 | 13 | 13 | 13 | 13 |
| (C) Solvent | C-1 | — | 40 | 40 | 40 | 40 |
| | C-2 | — | 45 | 45 | 45 | 45 |

| | | | | |
|---|---|---|---|---|
| Total | 100 | 100 | 100 | 100 |

TABLE 3
(unit: wt %)

| | | Solid content | Comparative Example | | |
|---|---|---|---|---|---|
| | | (wt %) | 1 | 2 | 3 |
| (A) Colorant | A-9 | 100 | 2 | — | — |
| | A-10 | 100 | — | 2 | — |
| | A-11 | 100 | — | — | 2 |
| (B) Binder resin | | 100 | 13 | 13 | 13 |
| (C) Solvent | C-1 | — | 40 | 40 | 40 |
| | C-2 | — | 45 | 45 | 45 |

| | | | |
|---|---|---|---|
| Total | 100 | 100 | 100 |

### (Evaluation)

### Evaluation 1: Evaluation of Wavelength Matching Properties

The near-infrared absorbing resin compositions according to Examples 1 to 8 and Comparative Examples 1 to 3 were respectively used to manufacture optical filter specimens.

Specifically, each of the near-infrared absorbing resin compositions was applied to a thickness of 1 μm to 3 μm on a 1 mm-thick degreased and washed glass substrate, and dried on a hot plate at 90° C. for 2 minutes to obtain optical filter specimens on which a near-infrared absorbing film was formed.

Each optical filter specimen was examined with respect to wavelength matching properties through a maximum absorption wavelength (λmax). Specifically, a UV-Vis-NIR spectrometer (UV-3600 Plus, Shimadzu Scientific instruments) was used to confirm the maximum absorption wavelength (λmax) of each optical filter specimen and simultaneously, measure absorbance intensity at the wavelength. The maximum absorption wavelength measured is shown in Table 4.

TABLE 4

| | Maximum absorption |
|---|---|
| | wavelength (wavelength |
| | matching properties) |
| Example 1 | 756 nm |
| Example 2 | 771 nm |
| Example 3 | 751 nm |
| Example 4 | 776 nm |
| Example 5 | 778 nm |
| Example 6 | 775 nm |
| Example 7 | 783 nm |
| Example 8 | 786 nm |
| Example 9 | 765 nm |
| Comparative Example 1 | 715 nm |
| Comparative Example 2 | 716 nm |
| Comparative Example 3 | 680 nm |

Referring to Table 4, compared to the dyes according to Comparative Examples 1 to 3, the core-shell dyes according to Examples 1 to 8 were suitable for near-infrared absorption. Specifically, the core-shell dyes according to Examples 1 to 8 included the core represented by Chemical Formula 1. The core represented by Chemical Formula 1 is a compound having a structure in which an aniline moiety in a squarine (SQ)-based compound is replaced with a diamine naphthalene moiety, and the maximum absorption peak may shift to the long wavelength region compared to a squarine-based compound.

Accordingly, the core-shell dyes including the core represented by Chemical Formula 1 according to Examples 1 to 8 were suitable for near-infrared absorption, compared to a squarine-based compound core including an aniline moiety (Comparative Example 1) or a core-shell compound (Comparative Example 2) as well as a generally-known green pigment (Comparative Example 3).

On the other hand, Examples 1 to 8 exhibited almost the same effect due to a structure of the cores but different maximum absorption wavelengths depending on whether or not a halogen group (specifically, F) was introduced into the shells.

Specifically, when the cores had the same structure, if the halogen group was introduced into the shells, the maximum absorption wavelength moved toward a long wavelength region by about 20 nm or so, resulting in realizing much excellent matching properties with a near-infrared absorption wavelength band.

However, the introduction of the halogen group into the shells was optional.

In brief, the core-shell dye according to an embodiment exhibited excellent matching properties with the near-infrared absorption wavelength band as a single effect of the core represented by Chemical Formula 1; or a synergistic effect of the core represented by Chemical Formula 1 and the shell represented by Chemical Formula 2.

### Evaluation 2: Evaluation of Light Resistance and Chemical Resistance

(1) Light Resistance Evaluation: An optical filter specimen obtained under the same condition as Evaluation 1 was exposed to light by using a high-pressure mercury lamp having a main wavelength of 365 nm and then, dried in a 230° C. oven for 60 minutes.

The exposure-treated substrate as described above was measured with respect to absorption intensity at a maximum absorption wavelength (λmax) in the aforementioned method. This measurement value and the measurement value of Evaluation 1 were put in Chemical Formula 1 to quantify light resistance, and the results are shown in Table 5.

Light resistance=100%×{1−(light absorption intensity after exposure treatment)/(absorption intensity before exposure treatment)} [Equation 1]

(2) Chemical Resistance Evaluation: An optical filter specimen obtained under the same condition of Evaluation 1 was dipped in an NMP (N-methylpyrrolidone) solution at room temperature for 10 minutes.

The chemically-treated substrate was measured with respect to absorption intensity at a maximum absorption wavelength (λmax) in the aforementioned method. This measurement value and the measurement value of Evaluation 1 were put in Chemical Formula 2 to quantify chemical resistance, and the results are shown in Table 5.

Chemical resistance=100%×{1−(absorption intensity after chemical treatment)/(absorption intensity before chemical treatment) [Equation 2]

(3) Heat Resistance Evaluation: An optical filter specimen obtained under the same as in Evaluation 1 was treated at 230° C. in a convection oven for 60 minutes.

The high temperature-treated substrate was measured with respect to absorption intensity at a maximum absorption wavelength (λmax) in the aforementioned method. This measurement value and the measurement value of Evaluation 1 were put in Chemical Formula 3 to quantify heat resistance, and the results are shown in Table 5.

Heat resistance=100%×{1−(absorption intensity after high temperature exposure)/(absorption intensity before high temperature exposure)} [Equation 3]

TABLE 5

| | Light | Chemical | Heat |
|---|---|---|---|
| | resistance | resistance | resistance |
| Example 1 | 3.1% | 3.0% | 3.2% |
| Example 2 | 2.8% | 2.7% | 2.9% |
| Example 3 | 3.0% | 2.9% | 3.1% |
| Example 4 | 2.7% | 2.6% | 2.5% |
| Example 5 | 2.9% | 2.8% | 2.5% |
| Example 6 | 2.8% | 2.6% | 2.0% |
| Example 7 | 2.4% | 2.5% | 2.1% |
| Example 8 | 2.6% | 1.5% | 2.4% |
| Example 9 | 2.9% | 2.9% | 3.1% |
| Comparative Example 1 | 92% | 91% | 92.5% |
| Comparative Example 2 | 5.2% | 5.1% | 5.3% |
| Comparative Example 3 | 93% | 92% | 92.1% |

Referring to Table 5, the core-shell dyes of Examples 1 to 8 exhibited significantly improved durability (light resistance, chemical resistance, and heat resistance), compared to the dye of Comparative Example 1. Specifically, compared to each core-only dye of Comparative Examples 1 and 2, the core-shell dyes of Examples 1 to 8 further included the shell represented by Chemical Formula 2 to compensate for lack of durability in the core represented by Chemical Formula 1.

On the other hand, the dye of Comparative Example 2 had a core-shell structure and thus exhibited improved durability (light resistance, chemical resistance, and heat resistance), compared to the core-only dye of Comparative Example 1.

However, the core-shell dyes of Examples 1 to 8 were compounds having a structure of replacing an aniline moiety in a squarine (SQ)-based compound with a diamine naphthalene moiety and thus exhibited improved durability (light resistance, chemical resistance, and heat resistance), compared to the dye of Comparative Example 2.

Examples 1 to 8 exhibited almost the same effect with respect to shell structures but different durability depending on whether or not an epoxy group and/or a (meth)acrylate group was introduced into the cores.

Specifically, the (meth)acrylate group is a functional group contributing to improving the heat resistance, and the *—O—*(epoxy) group is a functional group contributing to improving the chemical resistance. Accordingly, compared to when the R¹ was not substituted, when substituted with at least one (meth)acrylate group, at least one *—O—* (epoxy) group, or a combination thereof, chemical resistance, heat resistance, etc. of the core were appropriately improved.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

1. A core-shell dye, consisting of:
a core represented by Chemical Formula 1; and
a shell surrounding the core and represented by Chemical Formula 2: 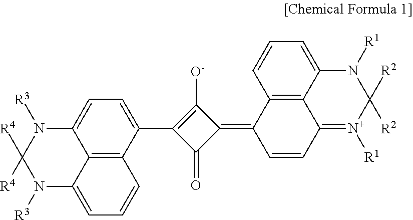
wherein, in Chemical Formula 1,
each R¹ is independently a substituted or unsubstituted C1 to C30 alkyl group, or a substituted or unsubstituted C6 to C30 aryl group;
each R² is independently a substituted or unsubstituted C1 to C30 alkyl group, a substituted or unsubstituted C6 to C30 aryl group, or a substituted or unsubstituted C1 to C30 arylalkyl group; adjacent two R e s are separate or are linked to each other to form a substituted or unsubstituted C3 to C30 cycloalkyl ring;
each R³ is independently a substituted or unsubstituted C1 to C30 alkyl group, or a substituted or unsubstituted C6 to C30 aryl group; and
each R⁴ is independently a substituted or unsubstituted C1 to C30 alkyl group, a substituted or unsubstituted C6 to C30 aryl group, or a substituted or unsubstituted C1 to C30 arylalkyl group; adjacent two R⁴ s are separate or are linked to each other to form a substituted or unsubstituted C3 to C30 cycloalkyl ring; 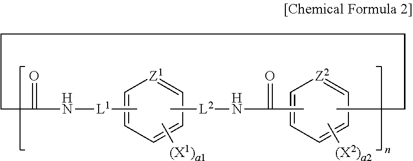
wherein, in Chemical Formula 2,
L¹ and L² are each independently a substituted or unsubstituted C1 to C10 alkylene group;
Z¹ and Z² are each independently *—CR—* or a nitrogen atom, in which R is a hydrogen atom or a substituted or unsubstituted C1 to C10 alkyl group;
X¹ and X² are each independently a halogen atom or a substituted or unsubstituted C1 to C10 alkyl group;
a1 and a2 are independently an integer of 0 to 4; and
n is an integer of 2 or more.

2. The core-shell dye of claim 1, wherein:
each R¹ is independently a substituted or unsubstituted C1 to C10 alkyl group, or a substituted or unsubstituted C6 to C10 aryl group; and
when IV is a substituted C1 to C10 alkyl group or a substituted C6 to C10 aryl group, the substituent of R¹ includes a (meth)acrylate group, a *—O—* (epoxy) group, or a combination thereof.

3. The core-shell dye of claim 1, wherein:
each R² is independently a substituted or unsubstituted C1 to C10 alkyl group or a substituted or unsubstituted C1 to C10 arylalkyl group; adjacent two R e s are separate or are linked to each other to form a C1 to C10 cycloalkyl ring that is substituted or unsubstituted with a C1 to C5 alkyl group; and
when R² is a substituted C1 to C10 alkyl group or a substituted C1 to C10 arylalkyl group, the substituent of R² is includes a C1 to C5 alkyl group.

4. The core-shell dye of claim 1, wherein:
each R³ is independently a substituted or unsubstituted C1 to C10 alkyl group or a substituted or unsubstituted C6 to C10 aryl group; and
when R³ is a substituted C1 to C10 alkyl group or a substituted or unsubstituted C6 to C10 aryl group, the Rail substituent of R³ includes a (meth)acrylate group, a *—O—* (epoxy) group, or a combination thereof.

5. The core-shell dye of claim 1, wherein:
each R⁴ is independently a substituted or unsubstituted C1 to C10 alkyl group or a substituted or unsubstituted C1 to C10 arylalkyl group; adjacent two R⁴s are separate or are linked to each other to form a C1 to C10 cycloalkyl ring unsubstituted or substituted with a C1 to C5 alkyl group; and
when R⁴ is a substituted C1 to C10 alkyl group or a substituted C1 to C10 arylalkyl group, the substituent of R⁴ is at least one C1 to C5 alkyl group.

6. The core-shell dye of claim 1, wherein the core represented by Chemical Formula 1 has a symmetrical structure.

7. The core-shell dye of claim 1, wherein:
the core represented by Chemical Formula 1 is represented by any one of Chemical Formulas 1-1 to 1-4: 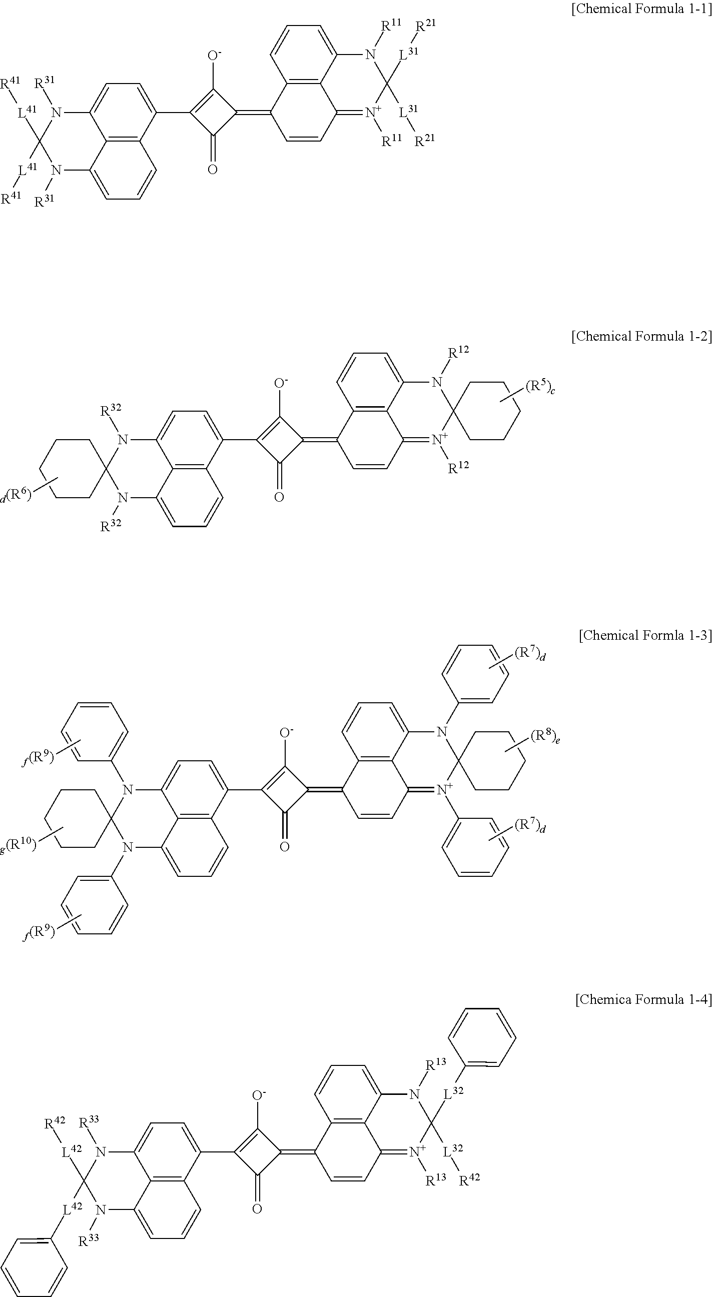
wherein, in Chemical Formula 1-1 to 1-4,
R¹¹, R¹², R¹³, R²¹, R³¹, R³², R³³, R⁴¹, and R⁴² are each independently a substituted or unsubstituted C1 to C10 alkyl group;
L³¹, L³², L⁴¹, and L⁴² are each independently a substituted or unsubstituted C1 to C10 alkylene group;
R⁵, R⁶, R⁸, and R¹⁰ are each independently a substituted or unsubstituted C1 to C10 alkyl group;
R⁷ and R⁹ are each independently a (meth)acrylate group or *—O—*(epoxy) group; and
c, d, e, f, and g are each independently an integer of 0 to 5.

8. The core-shell dye of claim 7, wherein:
the core represented by Chemical Formula 1 is represented by any one of the following Chemical Formulae: 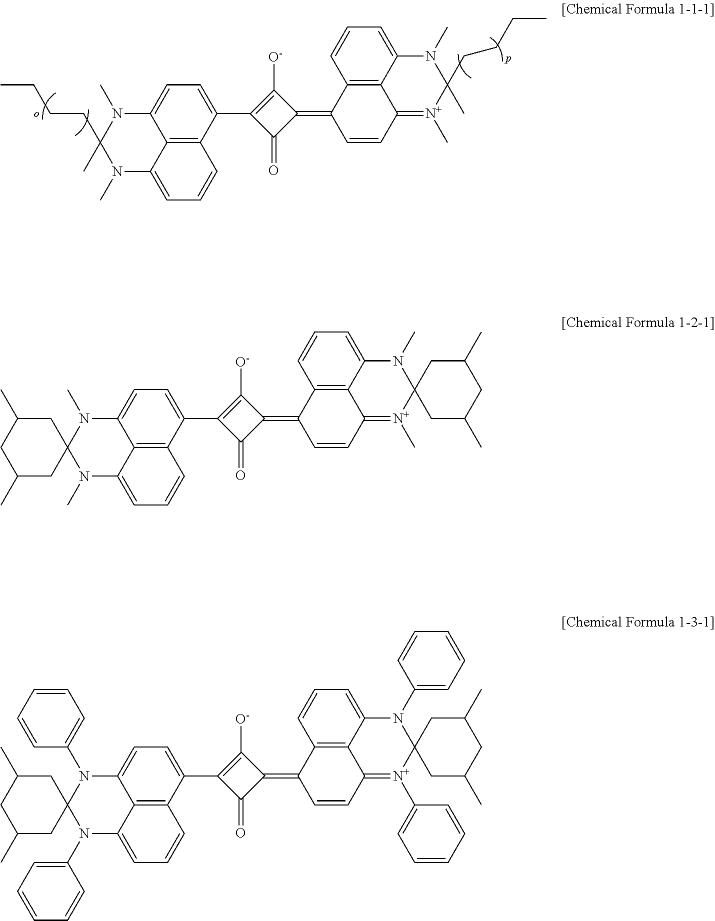 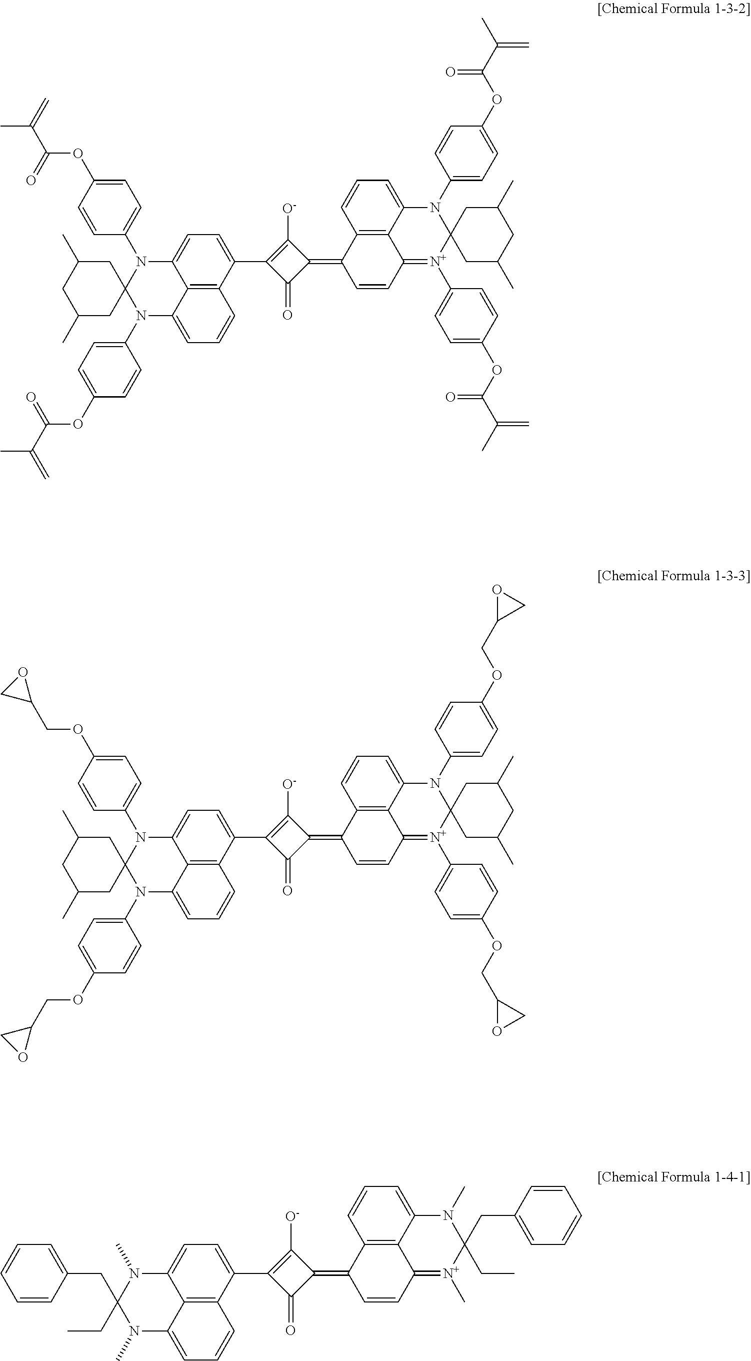
in Chemical Formula 1-1-1, o and p are each independently an integer of 0 to 5.

9. The core-shell dye of claim 1, wherein:
one of Z¹ and Z² is *—CH—* or a nitrogen atom, and
the other of V and Z² is *—CH—*.

10. The core-shell dye of claim 1, wherein:
X¹ and X² are each independently a halogen atom, and
a1+a2 is an integer of 1 to 8.

11. The core-shell dye of claim 1, wherein then is 2.

12. The core-shell dye of claim 1, wherein L¹ and L² are each independently an unsubstituted C1 to C10 alkylene group.

13. The core-shell dye of claim 1, wherein the shell is represented by any one of Chemical Formulas 2-1 to 2-4:

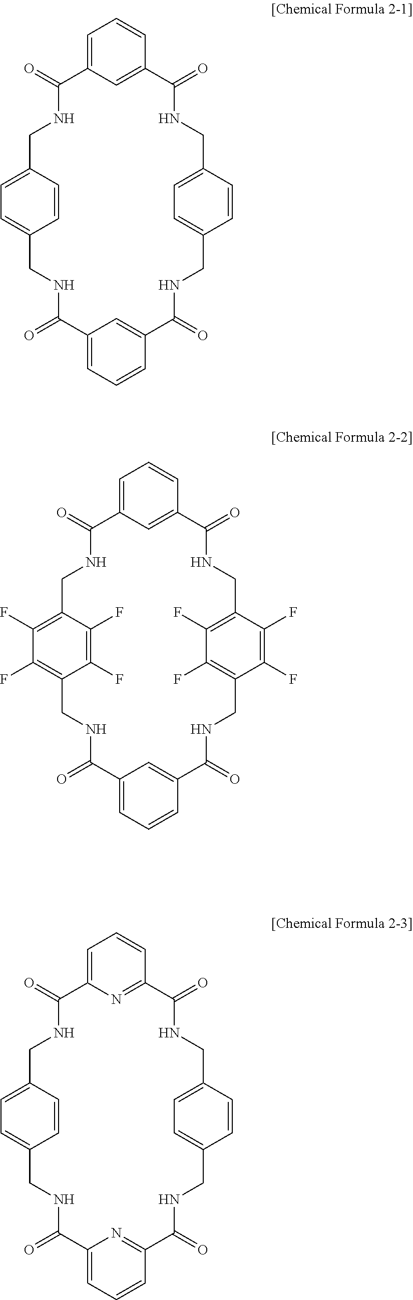 [SMILES: O=C1NCc2ccc(cc2)CNC(=O)c2cccc(c2)C(=O)NCc2ccc(cc2)CNC(=O)c2cccc1c2 ; O=C1NCc2c(F)c(F)c(c(F)c2F)CNC(=O)c2cccc(c2)C(=O)NCc2c(F)c(F)c(c(F)c2F)CNC(=O)c2cccc1c2 ; O=C1NCc2ccc(cc2)CNC(=O)c2cccc(n2)C(=O)NCc2ccc(cc2)CNC(=O)c2cccc1n2]

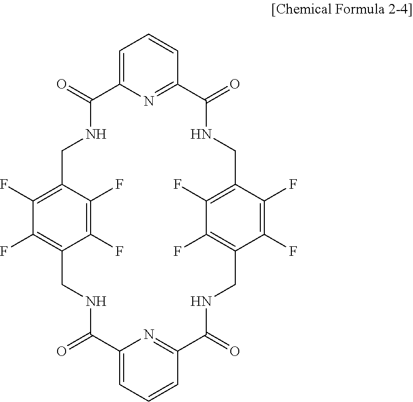 [SMILES: O=C1NCc2c(F)c(F)c(c(F)c2F)CNC(=O)c2cccc(n2)C(=O)NCc2c(F)c(F)c(c(F)c2F)CNC(=O)c2cccc1n2]

14. The core-shell dye of claim 1, wherein the core-shell dye includes the core and the shell in a mole ratio of 1:1.

15. The core-shell dye of claim 1, wherein:
the core-shell dye is represented by one of the following Chemical Formulae: 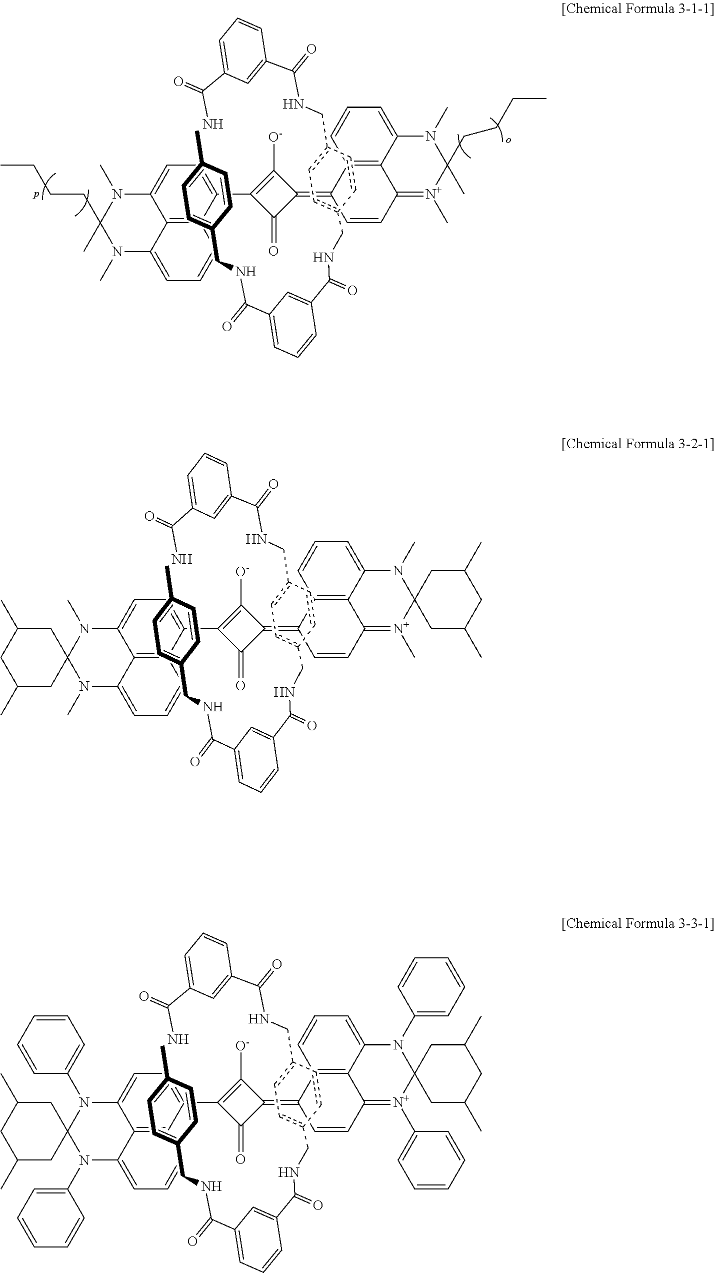 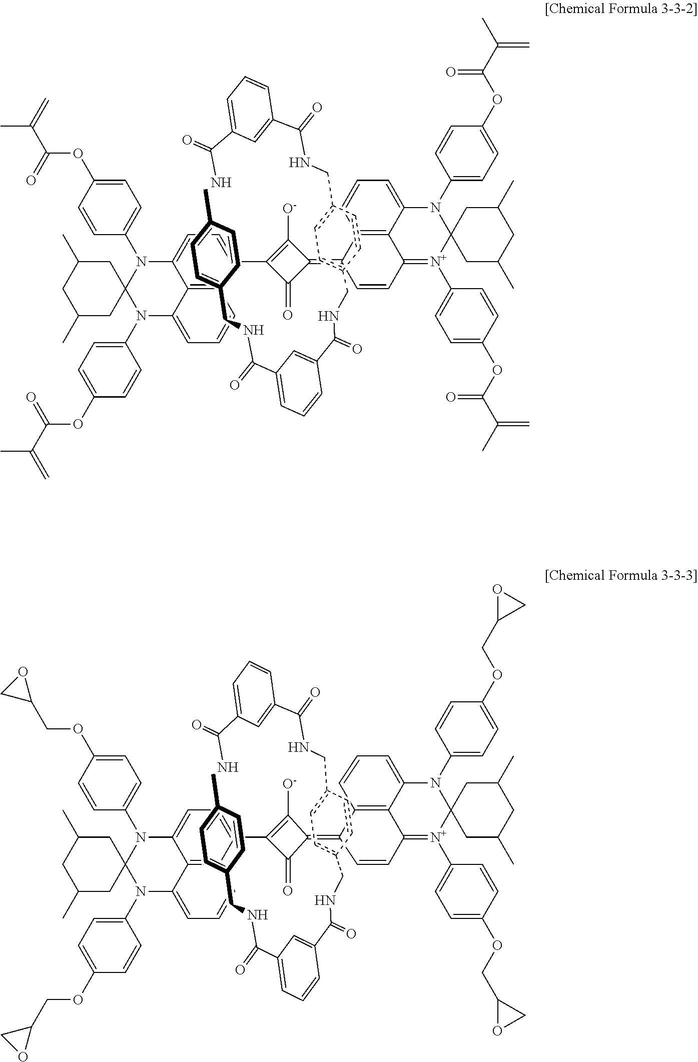 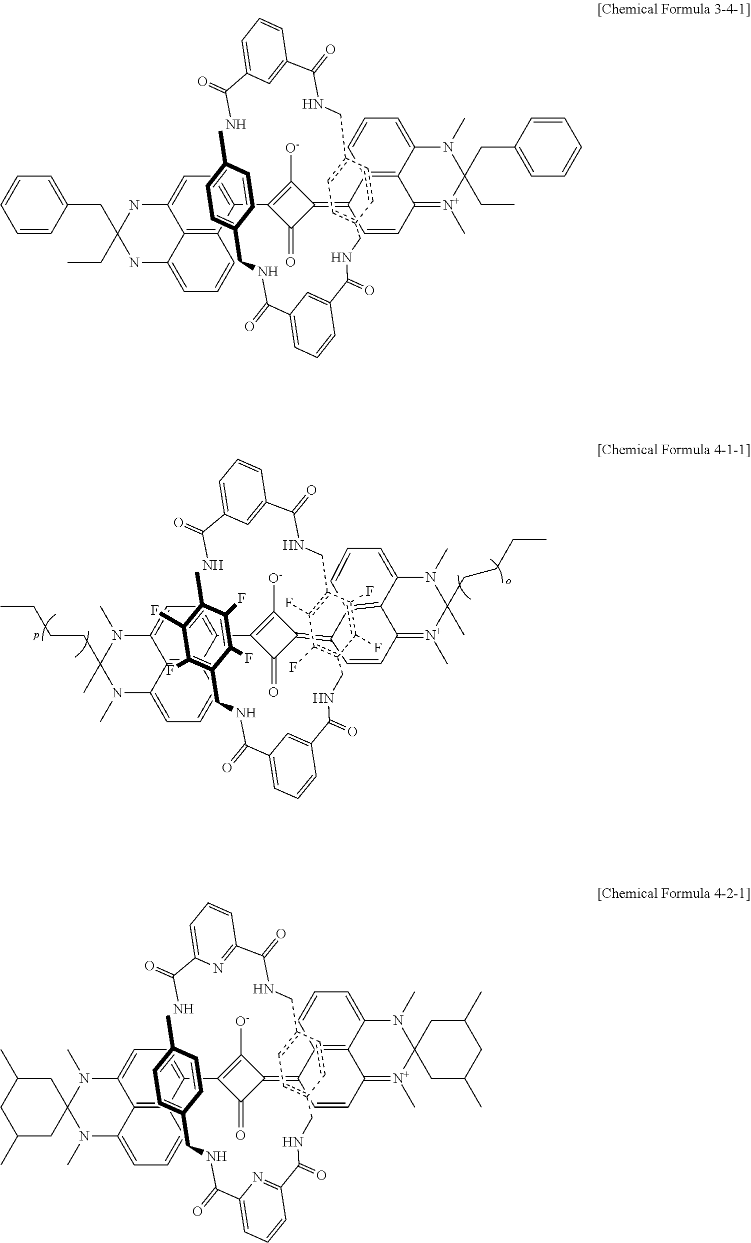 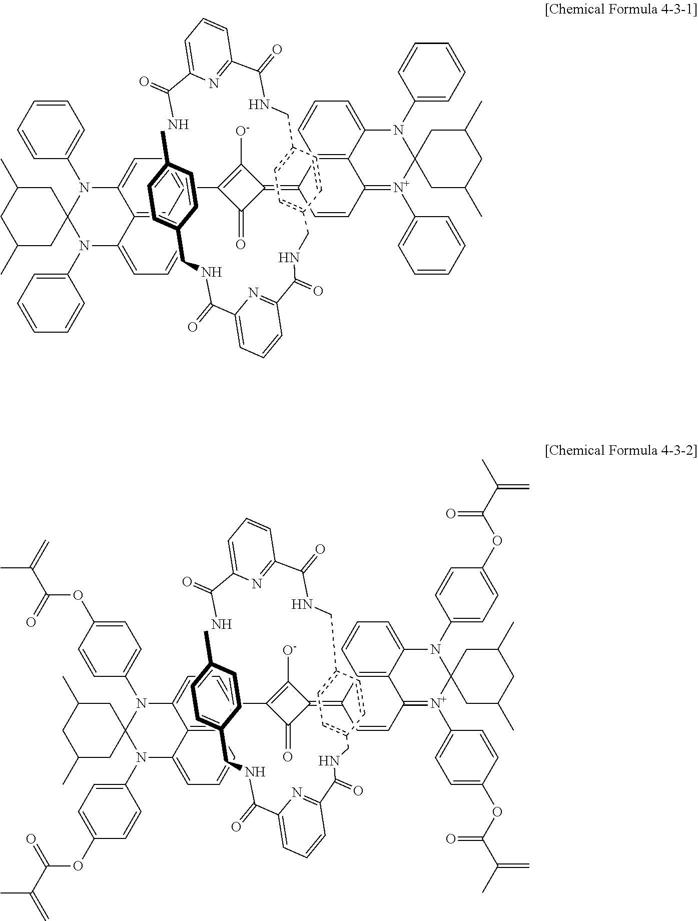 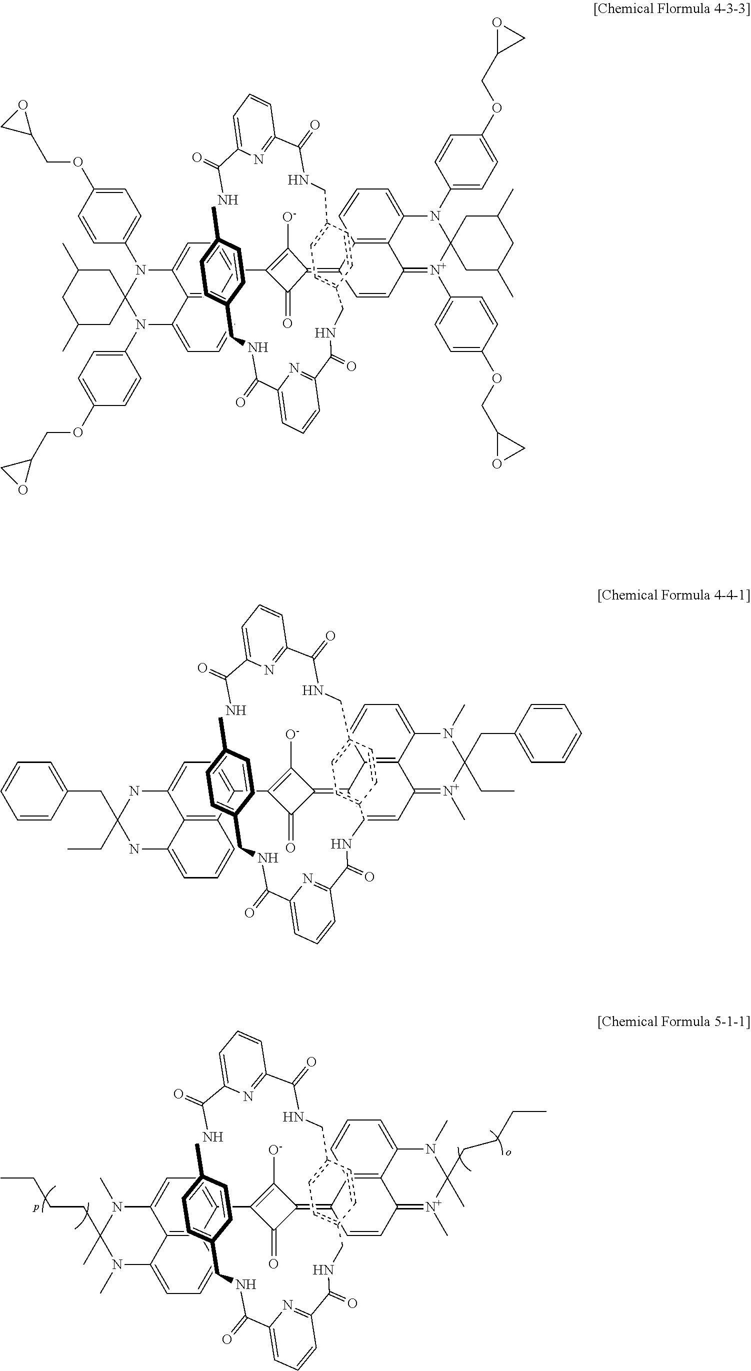 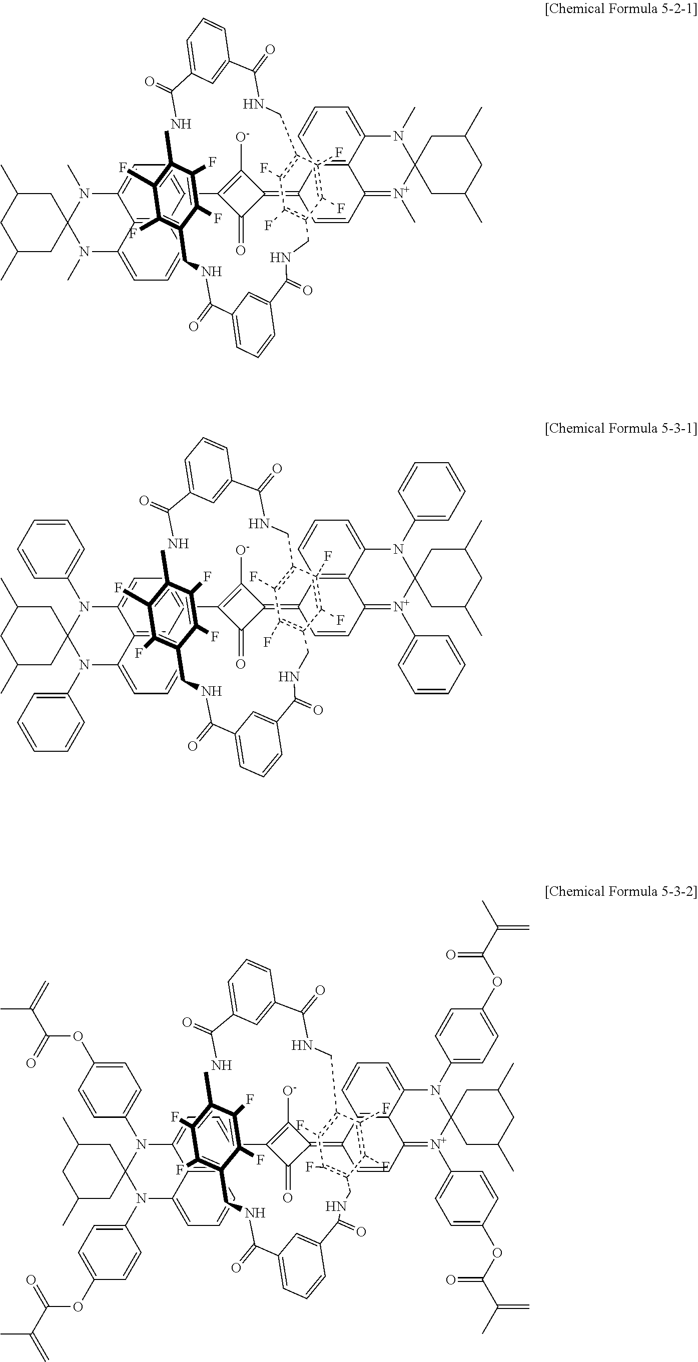 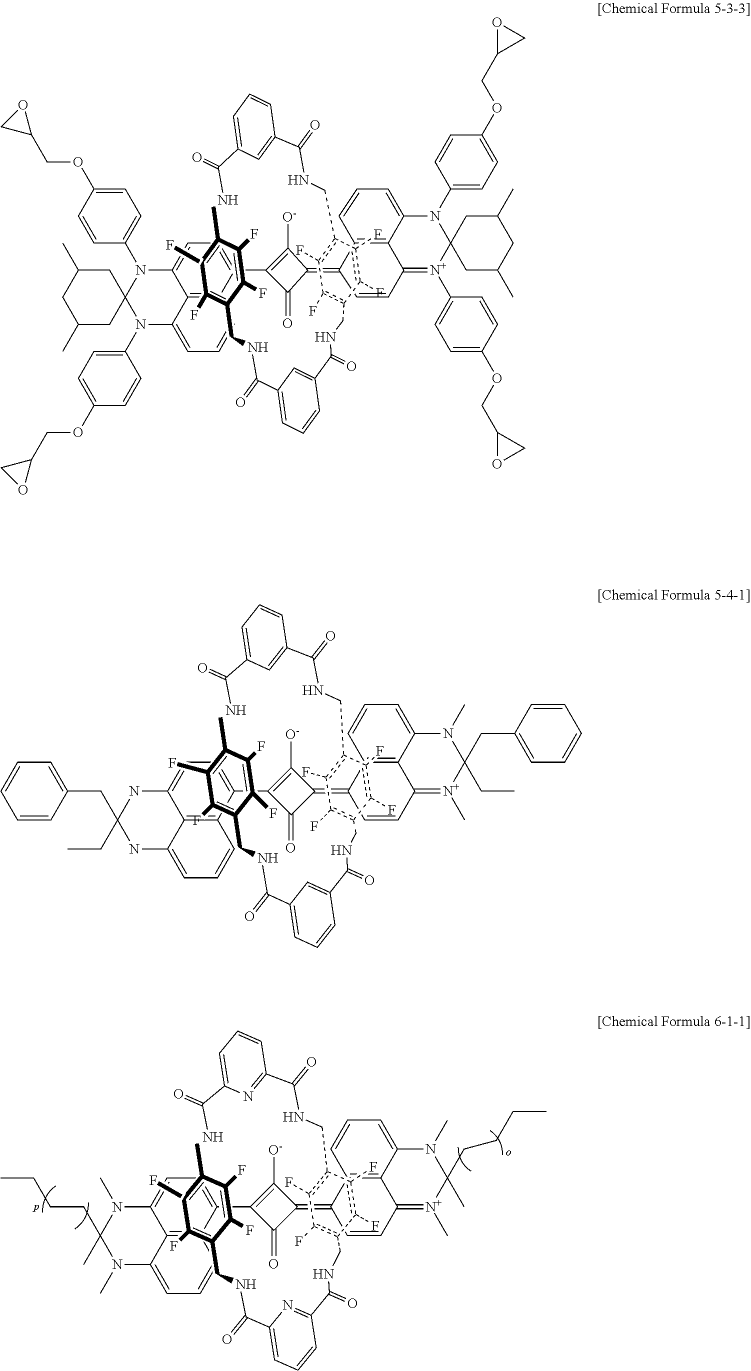 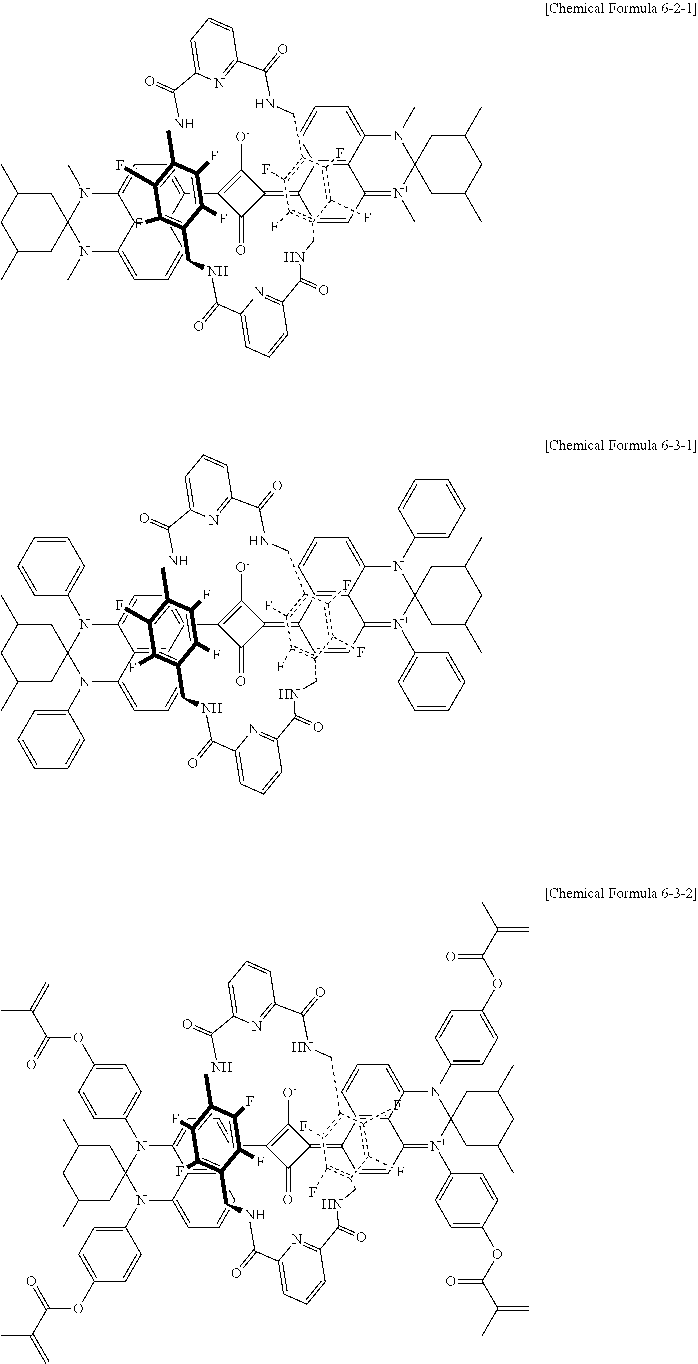 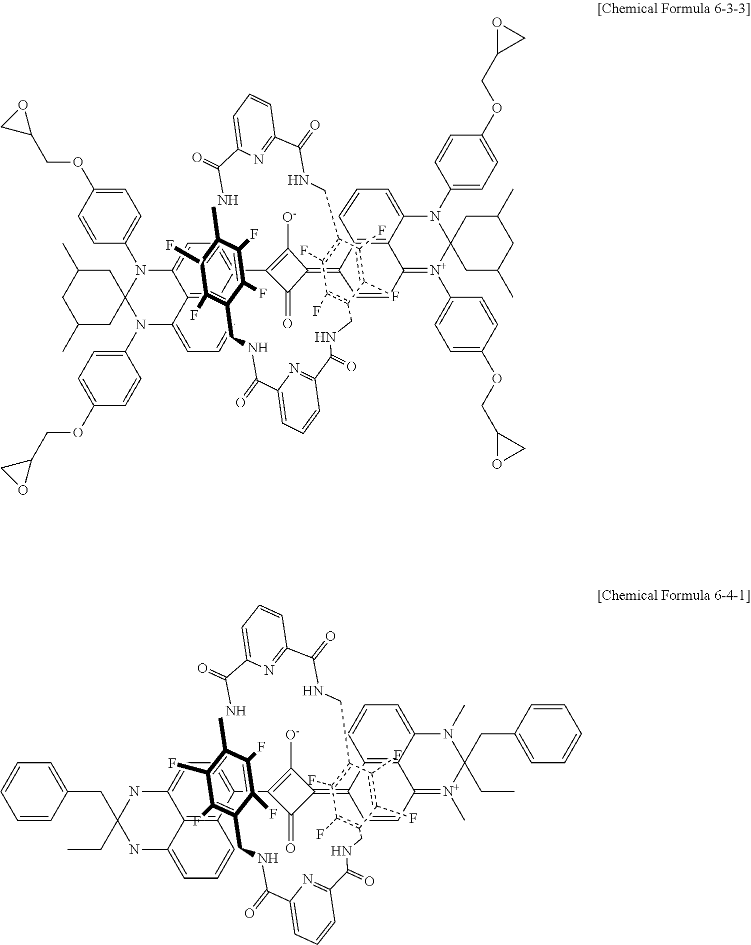
in Chemical Formula 3-1-1, Chemical Formula 4-1-1, Chemical Formula 5-1-1, and Chemical Formula 6-1-1, o and p are each independently an integer of 0 to 5.

16. The core-shell dye of claim 1, wherein the core has a maximum absorption peak at a wavelength of 700 nm to 850 nm.

17. The core-shell dye of claim 16, wherein the core-shell dye has a maximum absorption peak at a wavelength of 700 nm to 1,000 nm.

18. The core-shell dye of claim 1, wherein the core-shell dye is a near-infrared absorbing dye.

19. A near-infrared absorbing resin composition comprising the core-shell dye of claim 1.

20. The near-infrared absorbing resin composition of claim 19, further comprising a binder resin and a solvent.

21. The near-infrared absorbing resin composition of claim 19, wherein the near-infrared absorbing resin composition is used for a CMOS image sensor.

22. A near-infrared absorbing film manufactured using the near-infrared absorbing resin composition of claim 20.

23. An optical filter comprising the near-infrared absorbing film of claim 23.

24. A CMOS image sensor comprising the optical filter of claim 23.
